(19) United States
(12) Patent Application Publication
(10) Pub. No.: US 2024/0320391 A1
(43) Pub. Date: Sep. 26, 2024

(54) INSPECTION METHOD, INSPECTION PROGRAM, DATA CREATION METHOD, AND STORAGE MEDIUM

(71) Applicant: Kioxia Corporation, Tokyo (JP)

(72) Inventor: Mitsuyo ASANO, Yokohama Kanagawa (JP)

(73) Assignee: Kioxia Corporation, Tokyo (JP)

(21) Appl. No.: 18/600,724

(22) Filed: Mar. 10, 2024

(30) Foreign Application Priority Data
Mar. 22, 2023 (JP) 2023-045842

(51) Int. Cl. G06F 30/20; G06T 7/00; G06T 7/60; G06T 7/73

(52) U.S. Cl. CPC G06F 30/20; G06T 7/0006; G06T 7/60; G06T 7/73; G06T 2207/30148

(57) ABSTRACT

According to one embodiment, there is provided an inspection method. The method includes: extracting a skeleton in a plurality of patterns using data including the plurality of patterns; and inspecting whether a pattern width of the plurality of patterns or an inter-pattern distance between the plurality of patterns, satisfies a criterion based on the extracted skeleton.

### CROSS-REFERENCE TO RELATED APPLICATIONS

This application is based upon and claims the benefit of Japanese Patent Application No. 2023-045842, filed on Mar. 10, 2023; the entire contents of which are incorporated herein by reference.

### FIELD

Embodiments described herein relate generally to an inspection method, an inspection program, a data creation method, and a storage medium.

### BACKGROUND

The semiconductor device manufacturing step includes an inspection to check whether the designed layout configuration satisfies physical design criteria (referred to as mask rules). When the designed layout configuration satisfies the mask rules, a mask is manufactured and used for exposure and development of a semiconductor substrate. With this procedure, a semiconductor device having a device pattern according to the designed layout configuration is manufactured. The semiconductor device manufacturing step desirably can manufacture semiconductor devices appropriately.

### BRIEF DESCRIPTION OF THE DRAWINGS

FIG. 1 is a flowchart illustrating a method of manufacturing a semiconductor device to which an inspection method according to an embodiment is applied;

FIG. 2 is a diagram illustrating a functional configuration of a system to which the inspection method according to the embodiment is applied;

FIG. 3 is a diagram illustrating a hardware configuration of the system to which the inspection method according to the embodiment is applied;

FIG. 4 is a diagram illustrating a layout configuration of a plurality of patterns in the embodiment;

FIG. 5 is a diagram illustrating an extracted skeleton in the embodiment;

FIG. 6 is a diagram illustrating a pattern width and an inter-pattern distance in the embodiment;

FIG. 7 is a flowchart illustrating inspection processing in the embodiment;

FIG. 8 is a flowchart illustrating pattern skeleton extraction processing in a first modification of the embodiment;

FIG. 9 is a diagram illustrating pattern skeleton extraction processing in the first modification of the embodiment;

FIG. 10 is a flowchart illustrating pattern data inspection processing including inspection target exclusion setting according to a second modification of the embodiment;

FIGS. 11A and 11B are diagrams illustrating an inspection target exclusion setting in the second modification of the embodiment;

FIGS. 12A and 12B are diagrams illustrating an inspection target exclusion setting in the second modification of the embodiment;

FIG. 13 is a flowchart illustrating correction processing in a third modification of the embodiment;

FIG. 14 is a diagram illustrating correction processing in the third modification of the embodiment;

FIGS. 15A and 15B are diagrams illustrating a utilization example of an extracted skeleton in a fourth modification of the embodiment;

FIG. 16 is a diagram illustrating a utilization example of the extracted skeleton in the fourth modification of the embodiment;

FIGS. 17A to 17C are diagrams illustrating utilization examples of the extracted skeleton in the fourth modification of the embodiment;

FIG. 18 is a diagram illustrating a relationship between pattern complexity and a pattern information compression ratio in the fourth modification of the embodiment;

FIGS. 19A and 19B are diagrams illustrating search target figures according to the fourth modification of the embodiment;

FIGS. 20A to 20D are diagrams illustrating examples of figures in drawing data according to the fourth modification of the embodiment; and

FIG. 21 is a flowchart illustrating pattern skeleton extraction processing according to the fourth modification of the embodiment.

### DETAILED DESCRIPTION

In general, according to one embodiment, there is provided an inspection method. The method includes: extracting a skeleton in a plurality of patterns using data including the plurality of patterns; and inspecting whether a pattern width of the plurality of patterns or an inter-pattern distance between the plurality of patterns, satisfies a criterion based on the extracted skeleton.

Exemplary embodiments of an inspection method will be explained below in detail with reference to the accompanying drawings. The present invention is not limited to the following embodiments.

### Embodiments

The inspection method according to the embodiment is applied to an inspection as to whether a designed layout configuration in a manufacturing step of a semiconductor device satisfies physical design standards (mask rules), and has a specific configuration for appropriately performing the inspection.

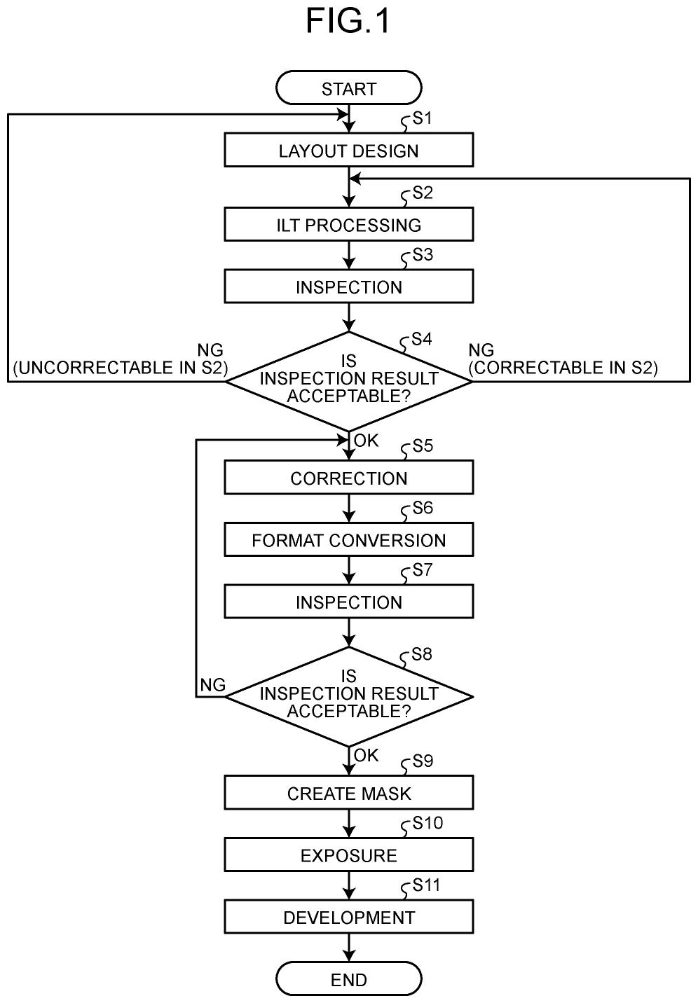

The manufacturing step of the semiconductor device includes steps of processing as schematically illustrated in FIG. 1. FIG. 1 is a flowchart illustrating a method of manufacturing a semiconductor device to which an inspection method according to an embodiment is applied. FIG. 1 illustrates examples of processing corresponding to the inspection method according to the embodiment, as inspection processing S3 and S7.

A semiconductor device manufacturing step includes schematic diagram design (circuit design), and generation of schematic data. A layout diagram is designed (as layout design) according to the schematic data by a layout editor so as to generate layout data (S1). The layout data includes a plurality of patterns.

The layout data is subjected to Inverse Lithography Technology (ILT) processing so as to generate mask data (S2). Details of the ILT processing will be described later.

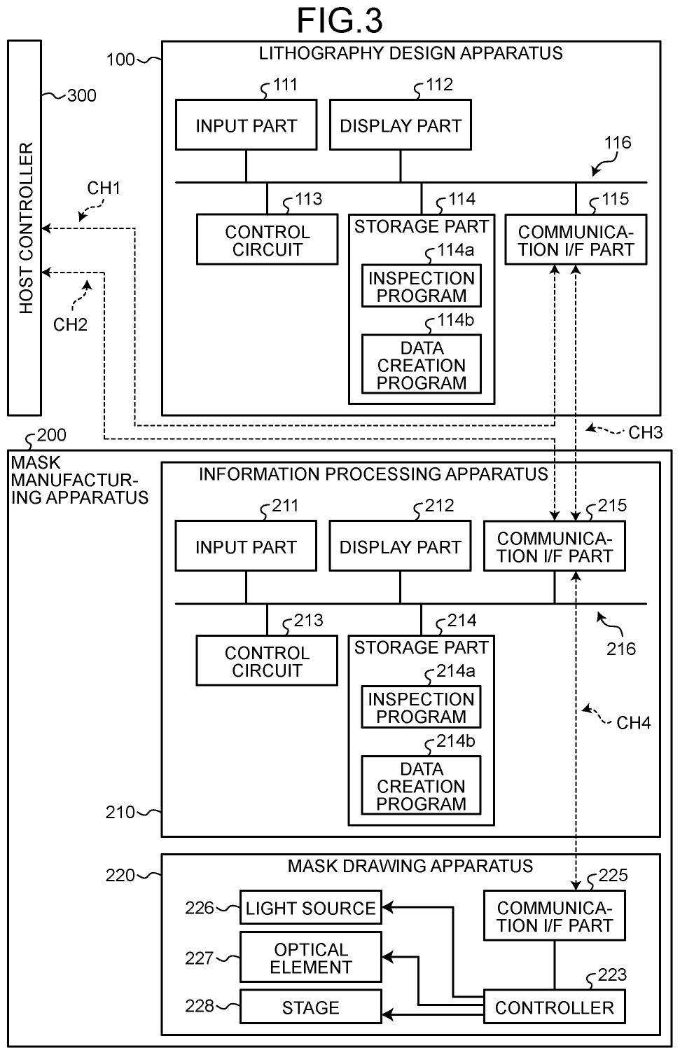

Following S2, an inspection program 114a (refer to FIG. 3) is executed for implementation of inspection processing S3. In the inspection processing S3, the skeleton in the plurality of patterns is extracted using the mask data generated by the ILT processing. Inspection referred to as mask rule check (MRC inspection) is performed based on the extracted skeleton. The MRC inspection can include inspection of whether a layout configuration of a plurality of patterns satisfies the mask rules.

Following the inspection processing S3, the result of the inspection processing S3 is confirmed (S4).

When the result of the inspection processing S3 is unacceptable and determined to be uncorrectable in S2 (‘NG (UNCORRECTABLE IN S2)’ in S4), the mask data is corrected with going back to LAYOUT DESIGN (S1). Alternatively, when the result of the inspection processing S3 is unacceptable and determined to be correctable in S2 (‘NG (CORRECTABLE IN S2)’ in S4), the mask data is corrected with going back to ILT PROCESSING (S2). The pattern edge position in the mask data can be corrected.

When the result of the inspection processing S3 is acceptable (OK in S4), the mask data generated by the ILT processing is corrected by mask process correction model (S5) and converted into the format of mask manufacturing mask data (S6).

Thereafter, an inspection program 214a (refer to FIG. 3) is executed for implementation of inspection processing S7. In the inspection processing S7, skeletons in a plurality of patterns are extracted using mask manufacturing mask data. MRC inspection is performed on the extracted skeleton. The MRC inspection can include inspection of whether a layout configuration of a plurality of patterns satisfies the mask rules.

Thereafter, the result of the inspection processing S7 is confirmed (S8).

When the result of the inspection processing S7 is unacceptable (NG in S8), the processing returns to S5 and the mask data is corrected and S6, S7 are performed again.

When the result of the inspection processing S7 is acceptable (OK in S8), a plurality of patterns corresponding to the mask data are drawn on the mask, and a mask is created (S9). A semiconductor substrate is exposed using the mask, a latent image is formed on a photosensitive material on a semiconductor substrate (S10), and the latent image is developed (S11), thereby manufacturing a semiconductor device having a device pattern according to the designed layout configuration.

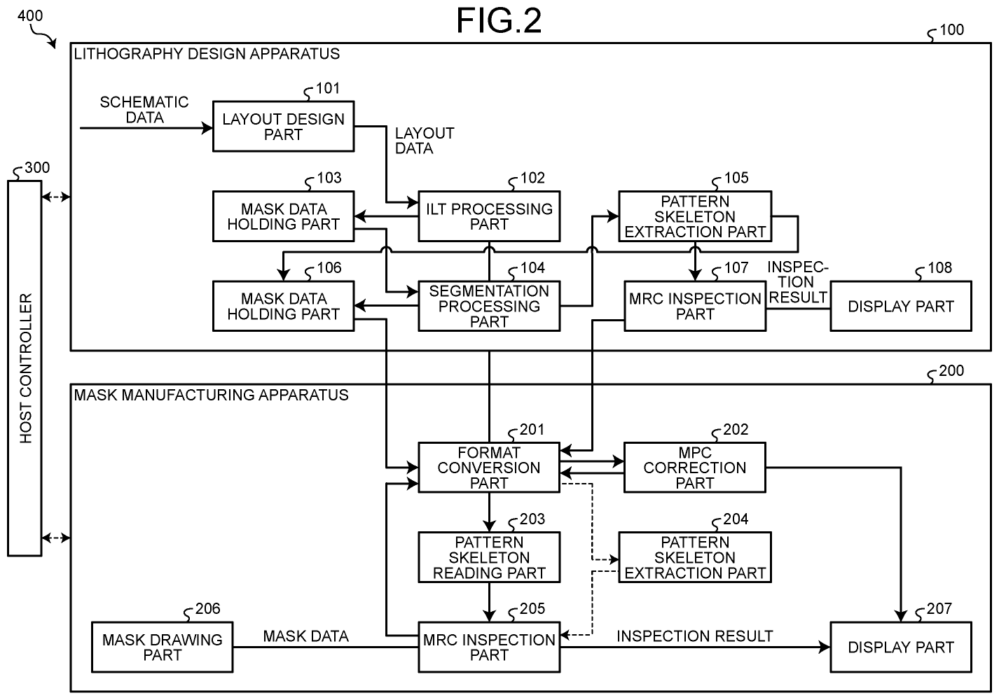

The processing of S1 to S9 are performed on a system 400, which can be functionally configured as illustrated in FIG. 2. FIG. 2 is a diagram illustrating a functional configuration of the system 400. The system 400 includes a lithography design apparatus 100, a mask manufacturing apparatus 200, and a host controller 300.

The host controller 300 integrally controls the lithography design apparatus 100 and the mask manufacturing apparatus 200. Note that the lithography design apparatus 100 and the mask manufacturing apparatus 200 may each include a local controller, and the lithography design apparatus 100 and the mask manufacturing apparatus 200 may be controlled independently of each other by each local controller.

Under the control of the host controller 300, the lithography design apparatus 100 generates mask data including a plurality of patterns to be applied to a mask in accordance with a designed layout configuration. The lithography design apparatus 100 includes a layout design part 101, an ILT processing part 102, a mask data holding part 103, a segmentation processing part 104, a pattern skeleton extraction part 105, a mask data holding part 106, an MRC inspection part 107, and a display part 108.

S1 illustrated in FIG. 1 is performed by the layout design part 101. S2 is performed by the ILT processing part 102 and the mask data holding part 103. S3 is performed by the mask data holding part 103, the segmentation processing part 104, the pattern skeleton extraction part 105, the mask data holding part 106, the MRC inspection part 107, and the display part 108. Note that the segmentation processing described below can be executed by the segmentation processing part 104, but can also be executed by the ILT processing part 102.

Under the control of the host controller 300 (or local controller), the mask manufacturing apparatus 200 illustrated in FIG. 2 performs predetermined processing on the mask data generated by the lithography design apparatus 100 and manufactures a mask using the processed mask data. The mask manufacturing apparatus 200 includes a format conversion part 201, a mask process correction (MPC) correction part 202, a pattern skeleton reading part 203, an MRC inspection part 205, a mask drawing part 206, and a display part 207.

S6 illustrated in FIG. 1 is performed by the format conversion part 201. S5 is performed by the MPC correction part 202. S7 is performed by the pattern skeleton reading part 203, the MRC inspection part 205, and the display part 207. S9 is performed by the mask drawing part 206.

The system 400 can have a hardware configuration as illustrated in FIG. 3. FIG. 3 is a diagram illustrating a hardware configuration of the system 400.

In the system 400, the host controller 300 and the lithography design apparatus 100 are connected to each other via a communication channel CH1. The host controller 300 and the mask manufacturing apparatus 200 are connected to each other via a communication channel CH2. The lithography design apparatus 100 and the mask manufacturing apparatus 200 are connected to each other via a communication channel CH3. Each of the communication channels CH1, CH2, and CH3 may be a wired communication channel or a wireless communication channel.

The lithography design apparatus 100 includes an input part 111, a display part 112, a control circuit 113, a storage part 114, and a communication I/F part 115. The input part 111, the display part 112, the control circuit 113, the storage part 114, and the communication I/F part 115 are communicably connected to each other via a bus 116.

The control circuit 113 integrally controls each part of the lithography design apparatus 100. The input part 111 receives a predetermined instruction from the user and supplies the predetermined instruction to the control circuit 113. The display part 112 displays predetermined information regarding the display screen under the control of the control circuit 113. The storage part 114 includes a buffer area serving as a work area for the control circuit 113 and a storage area capable of storing predetermined information. The storage part 114 may store an inspection program 114a and a data creation program 114b. The communication I/F part 115 is connected to the host controller 300 via the communication channel CH1 and is connected to the mask manufacturing apparatus 200 via the communication channel CH3.

When the control circuit 113 has executed the inspection program 114a and/or the data creation program 114b, the layout design part 101, the ILT processing part 102, the mask data holding part 103, the segmentation processing part 104, the pattern skeleton extraction part 105, the mask data holding part 106, and the MRC inspection part 107 (refer to FIG. 2) can be functionally constructed on the storage part 114 collectively at the time of compiling or sequentially in accordance with the progress of processing. The display part 112 corresponds to the display part 108 (refer to FIG. 2).

The mask control apparatus 200 includes an information processing apparatus 210 and a mask drawing apparatus 220.

The information processing apparatus 210 includes an input part 211, a display part 212, a control circuit 213, a storage part 214, and a communication I/F part 215. The input part 211, the display part 212, the control circuit 213, the storage part 214, and the communication I/F part 215 are communicably connected to each other via a bus 216.

The control circuit 213 integrally controls each part of the mask manufacturing apparatus 200. The input part 211 receives a predetermined instruction from the user and supplies the predetermined instruction to the control circuit 213. The display part 212 displays predetermined information regarding the display screen under the control of the control circuit 213. The storage part 214 includes a buffer area serving as a work area for the control circuit 213 and a storage area capable of storing predetermined information. The storage part 214 may store an inspection program 214a and a data creation program 214b. The communication I/F part 215 is connected to the host controller 300 via the communication channel CH1 and is connected to the mask manufacturing apparatus 200 via the communication channel CH3.

When the control circuit 213 has executed the inspection program 214a and/or the data creation program 214b, the format conversion part 201, the MPC correction part 202, the pattern skeleton reading part 203, the pattern skeleton extraction part 204, and MRC inspection part 205 (refer to FIG. 2) can be functionally constructed on the storage part 214 collectively at the time of compiling or sequentially in accordance with the progress of processing. The display part 212 corresponds to the display part 207 (refer to FIG. 2).

The mask drawing apparatus 220 includes a controller 223, a communication I/F part 225, a light source 226, an optical system 227, and a stage 228. The communication I/F part 225 is connected to the communication I/F part 215 via a communication path CH4 in the mask drawing apparatus 220. The controller 223 receives the mask data via the communication I/F part 225 and integrally controls each part of the mask drawing apparatus 220 in accordance with the mask data. The stage 228 is a location on which a mask used for drawing is mounted. The controller 223 drives the stage 228 to a predetermined target position via a drive part (not illustrated). The optical system 227 has a function of changing the traveling direction of an electron beam under the control of the controller 223. The light source 226 generates an electron beam and irradiates the mask on the stage 228 with the generated beam via the optical system 227 controlled by the controller 223. This makes it possible for the mask drawing apparatus 220 to draw a plurality of patterns corresponding to the mask data, on the mask.

The mask drawing apparatus 220 corresponds to the mask drawing part 206 (refer to FIG. 2).

In the lithography design apparatus 100 illustrated in FIG. 2, the layout design part 101 acquires schematic data from a circuit design apparatus (not illustrated). The layout design part 101 performs layout design based on the schematic data and/or an instruction from the user, and generates layout data. The layout design part 101 supplies the layout data to the ILT processing part 102.

The ILT processing part 102 performs ILT processing on the layout data. The ILT processing is reverse to optical proximity correction (OPC) processing of correcting a pattern on layout data to generate a pattern on mask data.

The ILT processing solves an inverse problem using a pattern on the layout data as an ideal optical image, thereby obtaining a pattern on the mask data. The mask data generated by the ILT processing is referred to as ILT mask data. The pattern on the ILT mask data can be regarded as an ideal pattern on the mask for obtaining the pattern on the layout data as an actual pattern. An ideal mask indicated by the ILT mask data will be referred to as an ILT ideal mask.

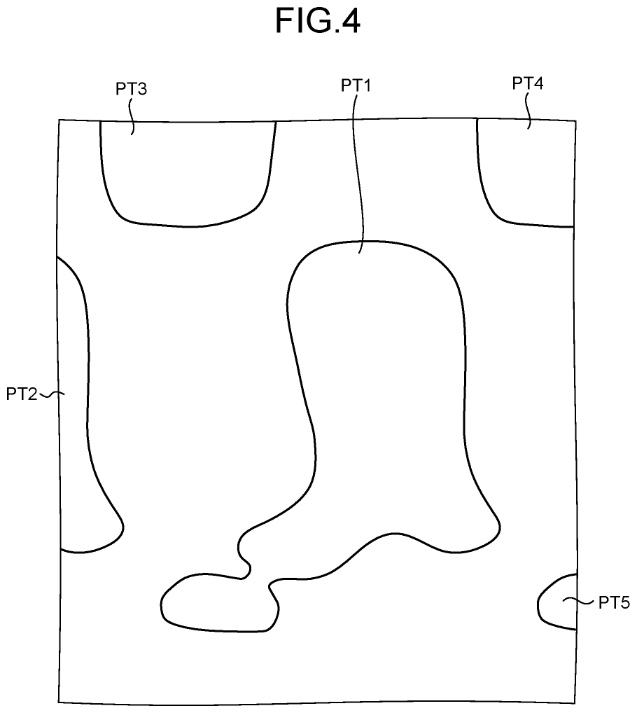

Unlike the pattern obtained by OPC correction, the pattern on the ILT mask data can include a complex curved shape. The ILT processing part 102 generates mask data including a plurality of patterns PT 1 to PT 5 as illustrated in FIG. 4, for example. Each pattern PT 1 to PT 5 may include a complex curve in its contour. FIG. 4 is a diagram illustrating a layout configuration of a plurality of patterns. FIG. 4 illustrates a layout configuration of a plurality of patterns generated by ILT processing. The ILT processing part 102 supplies ILT mask data to the mask data holding part 103.

The mask data holding part 103 illustrated in FIG. 2 holds the ILT mask data.

The segmentation processing part 104 acquires the ILT mask data from the mask data holding part 103 and performs segmentation processing on the ILT mask data.

For example, a transmissive mask includes an opening part and a light shielding part, and accordingly, data regarding the mask is binary data, which is data with a pattern and data without a pattern. In contrast, an ILT ideal mask is complicated in shape, and in addition, data regarding the mask is multi-valued data. The segmentation processing is performed to convert the ILT mask data into data that enables mask manufacturing and pattern writing.

In the segmentation processing, a plurality of patterns on the ILT mask data are regarded as a figure, and the figure is divided such that the figure has a predetermined complexity. The complexity of the figure can be defined by a minimum line segment length constituting the figure. The minimum line segment length can be predefined in accordance with the length of a line segment that can be drawn on the mask in mask manufacturing and pattern complexity for ensuring necessary lithography process latitude.

The segmentation processing part 104 supplies the ILT mask data that has been subjected to segmentation processing to the pattern skeleton extraction part 105 and the mask data holding part 106.

The pattern skeleton extraction part 105 acquires the ILT mask data subjected to the segmentation processing from the segmentation processing part 104, and extracts a pattern skeleton from each pattern of the ILT mask data. The pattern skeleton extraction part 105 may extract a skeleton IB within the pattern and a skeleton OB between a plurality of patterns using the ILT mask data.

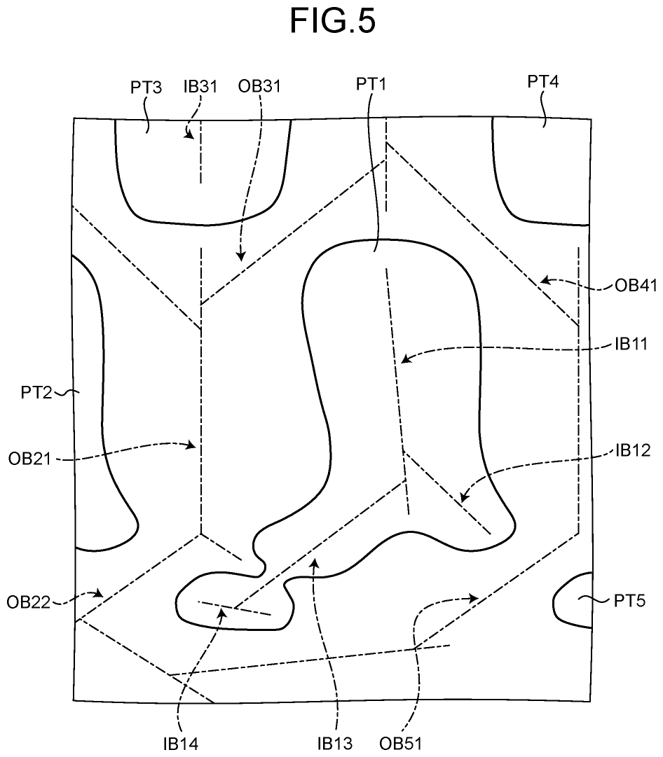

For example, when the plurality of patterns PT 1 to PT 5 as illustrated in FIG. 4 are generated by the ILT processing part 102, the pattern skeleton extraction part 105 extracts skeletons IB 11 to IB 14, and IB 31 within the patterns and skeletons OB 21, OB 22, OB 31, OB 41, and OB 51 between the patterns as indicated by one-dot chain lines in FIG. 5.

Skeletons IB 11 to IB 14 are skeletons in the pattern PT 1. The skeleton IB 31 is a skeleton in the pattern PT 3. Although skeletons in the other patterns PT 2, 4, and 5 are also extracted, illustration is omitted in FIG. 4 for simplification.

The skeletons OB 21 and OB 22 are skeletons between the pattern PT 1 and the pattern PT 2. The skeleton OB 31 is a skeleton between the pattern PT 1 and the pattern PT 3. The skeleton OB 41 is a skeleton between the pattern PT 1 and the pattern PT 4. The skeleton OB 51 is a skeleton between the pattern PT 1 and the pattern PT 5.

The pattern skeleton extraction part 105 supplies data regarding the skeleton IB within the pattern and the skeleton OB between the plurality of patterns to the mask data holding part 106. The pattern skeleton extraction part 105 adds data regarding the skeleton IB within the pattern and the skeleton OB between the plurality of patterns to the ILT mask data, and supplies the combined data to the MRC inspection part 107.

The mask data holding part 106 receives the ILT mask data subjected to the segmentation processing from the segmentation processing part 104, and receives data regarding the skeleton IB within the pattern and the skeleton OB between the plurality of patterns from the pattern skeleton extraction part 105. The mask data holding part 106 may add data regarding the skeleton IB within the pattern and the skeleton OB between the plurality of patterns to the ILT mask data.

By adding the data of the skeleton IB within the pattern and the skeleton OB between the plurality of patterns to the ILT mask data, the MRC inspection performed by the lithography design apparatus 100 and the MRC inspection performed by the mask manufacturing apparatus 200 can be performed with a common dimensional definition. In addition, in the mask manufacturing apparatus 200, the processing of pattern skeleton extraction before the MRC inspection can be omitted.

The MRC inspection part 107 receives the ILT mask data including the skeletons IB and OB, from the pattern skeleton extraction part 105. The MRC inspection part 107 performs the MRC inspection using the ILT mask data including the skeletons IB and OB. The MRC inspection inspects whether the pattern width and the inter-pattern distance satisfy the mask rules based on the skeleton IB within the pattern and the skeleton OB between the plurality of patterns. The MRC inspection performed by the MRC inspection part 107 is an inspection for making sure that a plurality of patterns included in the mask data do not exceed limitations in mask manufacturing.

In the MRC inspection, the MRC inspection part 107 obtains a parameter W, which is a parameter related to the pattern width. The MRC inspection part 107 may obtain, as the parameter W, a parameter related to a distance between two points, specifically when the two points are present within a contour of one pattern and a line segment connecting the two points intersects the skeleton IB. The MRC inspection part 107 may obtain, as the parameter W, a length of a line segment connecting two points present within a contour of one pattern and intersecting the skeleton IB, and having a minimum distance between the two points.

The MRC inspection part 107 determines whether the parameter W satisfies a first criterion. The first criterion includes a criterion of not falling below a first specified value Wth. The first specified value Wth corresponds to an allowable lower limit value of the pattern width, that is, corresponds to a critical dimension of the pattern width achievable in the drawing, for example. When the parameter W satisfies the first criterion, the MRC inspection part 107 determines that the pattern width satisfies the mask rule. When the parameter W does not satisfy the first criterion, the MRC inspection part 107 determines that the pattern width does not satisfy the mask rule.

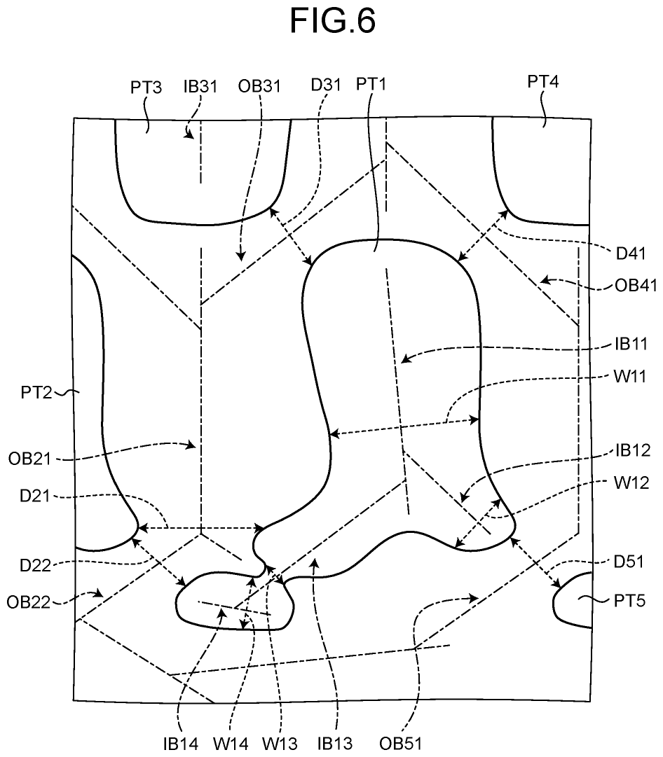

For example, when the skeletons IB 11 to IB 14 as illustrated in FIG. 5 are extracted by the pattern skeleton extraction part 105, the MRC inspection part 107 obtains a minimum length of the line segment intersecting the skeletons IB 11, IB 12, IB 13, and IB 14 within the pattern, as parameters W 11, W 12, W 13, and W 14 as indicated by dotted lines in FIG. 6. The MRC inspection part 107 compares each of the parameters W 11, W 12, W 13, and W 14 with the first specified value Wth. The MRC inspection part 107 determines whether the parameter W satisfies the first criterion based on the comparison result.

In addition, the MRC inspection part 107 obtains a parameter D regarding an inter-pattern distance. The MRC inspection part 107 may obtain, as the parameter D, a parameter related to a distance between two points, specifically when the two points are present separately in individual contours of two patterns and a line segment connecting the two points intersects a skeleton. The MRC inspection part 107 may obtain, as the parameter D, a length of a line segment connecting two points present separately in contours of two patterns and intersecting the skeleton OB, and having a minimum distance between the two points.

The MRC inspection part 107 determines whether the parameter D satisfies a second criterion. The second criterion includes a criterion of not falling below a second specified value Dth. The second specified value Dth corresponds to an allowable lower limit value of the inter-pattern distance, that is, corresponds to a critical dimension of the inter-pattern distance achievable in the drawing, for example. When the parameter D satisfies the second criterion, the MRC inspection part 107 determines that the inter-pattern distance satisfies the mask rule. When the parameter D does not satisfy the second criterion, the MRC inspection part 107 determines that the inter-pattern distance does not satisfy the mask rule.

For example, when skeletons OB 21, OB 22, OB 31, OB 41, and OB 51 as illustrated in FIG. 5 are extracted by the pattern skeleton extraction part 105, the MRC inspection part 107 obtains, as parameters D 21, D 22, D 31, D 41, and D 51, respectively, the lengths of the minimum line segments intersecting the skeletons OB 21, OB 22, OB 31, OB 41, and OB 51 between the patterns as indicated by dotted lines in FIG. 6. The MRC inspection part 107 compares each of the parameters D 21, D 22, D 31, D 41, and D 51 with the second specified value Dth. The MRC inspection part 107 determines whether the parameter D satisfies the second criterion based on a result of the comparison.

By performing such parameter definition, the MRC inspection part 107 can accurately inspect the distance between the nearest-neighbor vertices, between the segments, or between the vertices and the segments, in complex patterns.

Instead of such parameter definition, a length of a region having the same dimension in the same direction as that of the skeleton or having continuous MRC error dimensions may be defined as a same dimension continuous length or a run length. In this case, whether the pattern width or the inter-pattern distance satisfies the mask rule may be inspected depending on whether the same dimension continuous length or the run length satisfies a predetermined criterion.

The MRC inspection part 107 supplies an inspection result to the display part 108. The inspection result includes an inspection result as to whether each of the pattern width and the inter-pattern distance satisfies the mask rule. The display part 108 displays the inspection result on the display screen. The display part 108 may display the pattern PT, the skeleton IB within the pattern, the skeleton OB between the patterns, the parameter W, the parameter D, information as to whether the parameter W satisfies the first criterion, and information as to whether the parameter D satisfies the second criterion, on the display screen as illustrated in FIG. 6.

For example, it is allowable, in S4 illustrated in FIG. 1, to make a determination that the inspection result is unacceptable (NG) when the parameter W does not satisfy the first criterion or the parameter D does not satisfy the second criterion. It is allowable, in S4, to make a determination that the inspection result is acceptable (OK) when the parameter W satisfies the first criterion and the parameter D satisfies the second criterion.

In the mask manufacturing apparatus 200 illustrated in FIG. 2, the format conversion part 201 acquires ILT mask data from the mask data holding part 106. The format conversion part 201 converts the format of the ILT mask data into the format of mask manufacturing mask data. The mask manufacturing mask data is different from the ILT mask data in the data description format, but the data content is substantially similar. The mask manufacturing mask data includes a pattern PT, a skeleton IB within the pattern, and a skeleton OB between patterns as illustrated in FIG. 5.

The format conversion part 201 illustrated in FIG. 2 receives an inspection result from the MRC inspection part 107. The inspection result includes information regarding whether the parameter W, the parameter D, and the parameter W satisfy the first criterion, and information regarding whether the parameter D satisfies the second criterion. When the inspection result is unacceptable (NG), the format conversion part 201 supplies the inspection result and the mask data to the MPC correction part 202. When the inspection result is acceptable (OK), the format conversion part 201 holds the mask data.

The MPC correction part 202 supplies the inspection result and the mask data to the display part 207. The display part 207 displays the mask data on the display screen. The display part 207 may display the pattern PT, the skeleton IB within the pattern, the skeleton OB between the patterns, the parameter W, the parameter D, information as to whether the parameter W satisfies the first criterion, and information as to whether the parameter D satisfies the second criterion, on the display screen as illustrated in FIG. 6.

The MPC correction part 202 performs MPC correction based on an instruction from the user.

For example, when the parameter W 13 is less than the first specified value Wth, the MPC correction part 202 can receive an instruction to set the width of the portion corresponding to the parameter W 13 of the pattern PT 1 to the first specified value Wth or more. In response to this instruction, the MPC correction part 202 performs correction on the mask data to correct the width of the portion corresponding to the parameter W 13 in the pattern PT 1 to the first specified value Wth or more. The MPC correction part 202 may change the edge position and/or the dose of the portion corresponding to the parameter W 13 in the pattern PT 1 such that the width of the portion is set to the first specified value Wth or more.

Furthermore, when a pattern edge placement error caused by the mask process is known as an empirical rule, the MPC correction part 202 can receive an instruction to change the pattern width and/or the inter-pattern distance in accordance with the pattern edge placement error. In response to this instruction, the MPC correction part 202 performs correction of changing the pattern width and/or the inter-pattern distance to a desired width and/or a desired distance on the mask data. The MPC correction part 202 may change the edge position of the pattern and/or the dose of the pattern such that the pattern width and/or the inter-pattern distance is set to a desired width and/or a desired distance.

The MPC correction part 202 returns the corrected mask data to the format conversion part 201.

The pattern skeleton reading part 203 acquires the mask data from the format conversion part 201. The pattern skeleton reading part 203 reads, from the mask data, a pattern PT, a skeleton IB within the pattern, and the skeleton OB between the patterns. The pattern skeleton reading part 203 may read a pattern PT, a skeleton IB within the pattern, and a skeleton OB between patterns as illustrated in FIG. 5. The pattern skeleton reading part 203 supplies the read pattern PT, the skeleton IB within the pattern, and the skeleton OB between the patterns to the MRC inspection part 205.

The MRC inspection part 205 receives the pattern PT, the skeleton IB within the pattern, and the skeleton OB between the patterns from the pattern skeleton reading part 203. The MRC inspection part 205 performs the MRC inspection using the mask data including the skeletons IB and OB. The MRC inspection inspects whether the pattern width and the inter-pattern distance satisfy the mask rules based on the skeleton IB within the pattern and the skeleton OB between the plurality of patterns. The MRC inspection by the MRC inspection part 205 includes both an inspection for confirming whether a plurality of patterns included in the mask data exceed mask manufacturing limitations and an inspection for confirming whether the mask data includes a result of errors of format conversion by the format conversion part 201.

In the MRC inspection, the MRC inspection part 205 obtains a parameter W related to the pattern width. The MRC inspection part 205 may obtain, as the parameter W, a parameter related to a distance between two points, specifically when the two points are present within a contour of one pattern and a line segment connecting the two points intersects the skeleton IB. The MRC inspection part 205 may obtain, as the parameter W, a length of a line segment connecting two points present within a contour of one pattern and intersecting the skeleton IB, and having a minimum distance between the two points.

The MRC inspection part 205 determines whether the parameter W satisfies the first criterion. The first criterion includes a criterion of not falling below the first specified value Wth. The first specified value Wth corresponds to an allowable lower limit value of the pattern width, that is, corresponds to a critical dimension of the pattern width achievable in the drawing, for example. When the parameter W satisfies the first criterion, the MRC inspection part 205 determines that the pattern width satisfies the mask rule. When the parameter W does not satisfy the first criterion, the MRC inspection part 205 determines that the pattern width does not satisfy the mask rule.

For example, when the mask data includes the skeletons IB 11 to IB 14 as illustrated in FIG. 5, the MRC inspection part 205 obtains a minimum length of the line segment intersecting the skeletons IB 11, IB 12, IB 13, and IB 14 within the pattern, as parameters W 11, W 12, W 13, and W 14 as indicated by dotted lines in FIG. 6. The MRC inspection part 205 compares each of the parameters W 11, W 12, W 13, and W 14 with the first specified value Wth. The MRC inspection part 205 determines whether the parameter W satisfies the first criterion based on the comparison result.

In addition, the MRC inspection part 205 obtains a parameter D regarding an inter-pattern distance. The MRC inspection part 205 may obtain, as the parameter D, a parameter related to a distance between two points, specifically when the two points are present separately in individual contours of two patterns and a line segment connecting the two points intersects a skeleton. The MRC inspection part 205 may obtain, as the parameter D, a length of a line segment connecting two points present separately in contours of two patterns and intersecting the skeleton OB, and having a minimum distance between the two points.

The MRC inspection part 205 determines whether the parameter D satisfies a second criterion. The second criterion includes a criterion of not falling below a second specified value Dth. The second specified value Dth corresponds to an allowable lower limit value of the inter-pattern distance, that is, corresponds to a critical dimension of the inter-pattern distance achievable in the drawing, for example. When the parameter D satisfies the second criterion, the MRC inspection part 205 determines that the inter-pattern distance satisfies the mask rule. When the parameter D does not satisfy the second criterion, the MRC inspection part 205 determines that the inter-pattern distance does not satisfy the mask rule.

For example, when the mask data includes skeletons OB 21, OB 22, OB 31, OB 41, and OB 51 as illustrated in FIG. 5, the MRC inspection part 205 obtains, as parameters D 21, D 22, D 31, D 41, and D 51, the lengths of the minimum line segments intersecting the skeletons OB 21, OB 22, OB 31, OB 41, and OB 51 between the patterns as indicated by dotted lines in FIG. 6. The MRC inspection part 205 compares each of the parameters D 21, D 22, D 31, D 41, and D 51 with the second specified value Dth. The MRC inspection part 205 determines whether the parameter D satisfies the second criterion based on the comparison result.

By performing such parameter definition, the MRC inspection part 205 can accurately inspect the distance between the nearest-neighbor vertices, between the segments, or between the vertices and the segments, in complex patterns.

Instead of such parameter definition, a length of a region having the same dimension in the same direction as that of the skeleton or having continuous MRC error dimensions may be defined as a same dimension continuous length or a run length. In this case, whether the pattern width or the inter-pattern distance satisfies the mask rule may be inspected depending on whether the same dimension continuous length or the run length satisfies a predetermined criterion.

The MRC inspection part 205 supplies an inspection result to the display part 207. The inspection result includes an inspection result as to whether each of the pattern width and the inter-pattern distance satisfies the mask rule. The display part 207 displays the inspection result on the display screen. The display part 207 may display the pattern PT, the skeleton IB within the pattern, the skeleton OB between the patterns, the parameter W, the parameter D, information as to whether the parameter W satisfies the first criterion, and information as to whether the parameter D satisfies the second criterion, on the display screen as illustrated in FIG. 6.

For example, it is allowable, in S8 illustrated in FIG. 1, to make a determination that the inspection result is unacceptable (NG) when the parameter W does not satisfy the first criterion or the parameter D does not satisfy the second criterion. It is allowable, in S8, to make a determination that the inspection result is acceptable (OK) when the parameter W satisfies the first criterion and the parameter D satisfies the second criterion.

When the inspection result is acceptable (OK), the MRC inspection part 205 supplies the mask data to the mask drawing part 206.

The mask drawing part 206 draws a plurality of patterns corresponding to the mask data, on the mask. This leads to creation of a mask corresponding to the mask data.

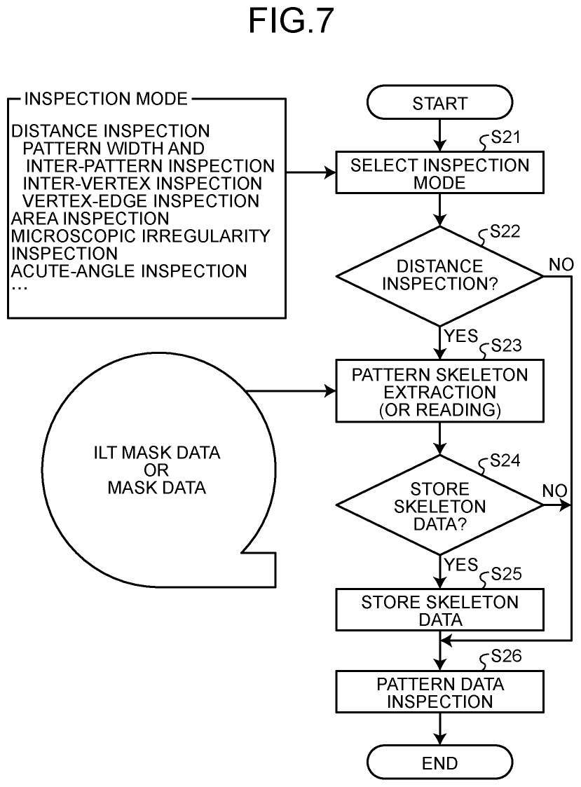

Next, a flow of the inspection processing S3 will be described with reference to FIG. 7. FIG. 7 is a flowchart illustrating inspection processing.

In the inspection processing S3, the lithography design apparatus 100 selects an inspection mode in accordance with the selection instruction from the user (S21). The inspection mode includes distance inspection, area inspection, small features inspection, and acute-angle inspection. The distance inspection includes a minimum pattern width/inter-pattern inspection, an inter-vertex inspection, and a vertex-edge inspection.

The lithography design apparatus 100 determines whether the inspection mode selected in S21 is distance inspection (S22).

When the inspection mode is not distance inspection (No in S22), the lithography design apparatus 100 performs predetermined settings or the like as necessary, and proceeds to the processing of S26.

When the inspection mode is the distance inspection (Yes in S22), the lithography design apparatus 100 extracts a pattern skeleton (S23). The lithography design apparatus 100 may acquire ILT mask data and extract the skeleton IB within the pattern and the skeleton OB between the plurality of patterns using the obtained ILT mask data.

The lithography design apparatus 100 determines whether to store data of the skeletons IB and OB (S24). When having determined not to store the data of the skeletons IB and OB (No in S24), the lithography design apparatus 100 proceeds to the processing of S26.

When having determined to store the data of the skeletons IB and OB (Yes in S24), the lithography design apparatus 100 adds the data of the skeletons IB and OB to the ILT mask data. With this operation, the lithography design apparatus 100 stores the data of the skeletons IB and OB in the ILT mask data (S25).

The lithography design apparatus 100 performs MRC inspection in the inspection mode selected in S21 using the ILT mask data (S26).

When the inspection mode selected in S21 is the distance inspection and the ILT mask data includes the skeletons IB and OB, the lithography design apparatus 100 performs the MRC inspection using the ILT mask data including the skeletons IB and OB. The lithography design apparatus 100 can inspect whether the pattern width and the inter-pattern distance satisfy the mask rules based on the skeleton IB within the pattern and the skeleton OB between the plurality of patterns.

When the inspection mode selected in S21 is another inspection or the ILT mask data does not include the skeletons IB or OB, the lithography design apparatus 100 performs the MRC inspection using the ILT mask data not including the skeletons IB or OB.

Next, a flow of the inspection processing S7 will be described with reference to FIG. 7.

In the inspection processing S7, the mask manufacturing apparatus 200 selects the inspection mode in accordance with the selection instruction from the user (S21). The inspection mode includes distance inspection, area inspection, microscopic irregularity inspection, and acute-angle inspection. The distance inspection includes a minimum pattern width/inter-pattern inspection, an inter-vertex inspection, and a vertex-edge inspection.

The mask manufacturing apparatus 200 determines whether the inspection mode selected in S21 is the distance inspection (S22).

When the inspection mode is not distance inspection (No in S22), the mask manufacturing apparatus 200 performs predetermined settings or the like as necessary, and proceeds to the processing of S26.

When the inspection mode is the distance inspection (Yes in S22), the mask manufacturing apparatus 200 reads the pattern skeleton (S23). The mask manufacturing apparatus 200 may acquire mask data and read the pattern PT, the skeleton IB within the pattern, and the skeleton OB between the patterns from the mask data.

The mask manufacturing apparatus 200 determines whether to store the data of the skeletons IB and OB (S24). When having determined not to store the data of the skeletons IB and OB (No in S24), the mask manufacturing apparatus 200 proceeds to the processing of S26.

When having determined to store the data of the skeletons IB and OB (Yes in S24), the mask manufacturing apparatus 200 adds the data of the skeletons IB and OB to the mask data. With this operation, the mask manufacturing apparatus 200 stores the data of the skeletons IB and OB in the mask data (S25).

The mask manufacturing apparatus 200 performs the MRC inspection in the inspection mode selected in S21 using the mask data (S26).

When the inspection mode selected in S21 is the distance inspection and the mask data include the skeletons IB and OB, the mask manufacturing apparatus 200 performs the MRC inspection using the mask data including the skeletons IB and OB. The mask manufacturing apparatus 200 can inspect whether the pattern width and the inter-pattern distance satisfy the mask rules based on the skeleton IB within the pattern and the skeleton OB between the plurality of patterns.

When the inspection mode selected in S21 is another inspection or the mask data does not include the skeletons IB or OB, the mask manufacturing apparatus 200 performs the MRC inspection using the mask data not including the skeletons IB or OB.

As described above, in the embodiment, a skeleton in a plurality of patterns is extracted using data including the plurality of patterns. Based on the extracted skeleton, an inspection is performed to check whether the layout configuration of the plurality of patterns satisfies the mask rules. This makes it possible to appropriately perform an inspection to check whether the layout configuration of the plurality of patterns satisfies the mask rules. This enables appropriate manufacturing of the mask, leading to appropriate manufacture of a semiconductor device using the mask. That is, according to the embodiment, it is possible to provide an inspection method suitable for appropriately manufacturing a semiconductor device.

Note that the processing of extracting the pattern skeleton may be performed in each of the inspection processing S3 and the inspection processing S7 (refer to FIG. 1). In this case, the mask manufacturing apparatus 200 illustrated in FIG. 2 may include a pattern skeleton extraction part 204 instead of the pattern skeleton reading part 203. The pattern skeleton extraction part 204 may extract a pattern skeleton for each pattern of the mask data, similarly to the pattern skeleton extraction part 105. The pattern skeleton extraction part 204 may extract a skeleton IB within the pattern and a skeleton OB between a plurality of patterns by using the mask data (refer to FIG. 5). Furthermore, in the lithography design apparatus 100, the processing of transferring the data of the skeletons IB and OB from the pattern skeleton extraction part 105 to the mask data holding part 106 may be omitted, and the mask data holding part 106 may hold the ILT mask data not including the data of the skeletons IB or OB.

In addition, the data format of data processed by the lithography design apparatus 100 and the mask control apparatus 200 may be any data format. In the lithography design apparatus 100, the layout design part 101, the ILT processing part 102, and the mask data holding part 103 may handle raster data, while the segmentation processing part 104 may convert the raster data into vector data. The mask data holding part 106, the MRC inspection part 107, and the display part 108 may handle vector data. Each part of the mask control apparatus 200 may handle vector data.

Furthermore, as a first modification of the embodiment, the skeleton within the pattern and the skeleton between the patterns in the ILT mask data and/or the mask data may be extracted by obtaining a locus of the center of a circle inscribed within the pattern and a locus of the center of a circle inscribed between the patterns.

The concept of pattern skeleton extraction (pattern skeleton formation) is traced back to the literature “H. Blum, Biological shape and visual science (part I), Journal of Theoretical Biology vol. 38, pp. 205-287 (1973)”, in which a propagation of wave front model and an inscribed disk model are proposed. Although the method of skeleton formation is not particularly limited since the pattern skeletons formed by the two models are considered to be equivalent, here, skeleton formation is performed based on the inscribed disk model.

Regarding the data for pattern skeleton formation, data obtained by performing segmentation processing on the ILT ideal mask figure output by the ILT processing may be used. In addition, the following will give an exemplary case where the data format to be handled is vector data including a description of vertex coordinate information constituting each figure. In this example, it is assumed that the direction of the line segment connecting the vertices is 0 degrees or 90 degrees with respect to the reference direction.

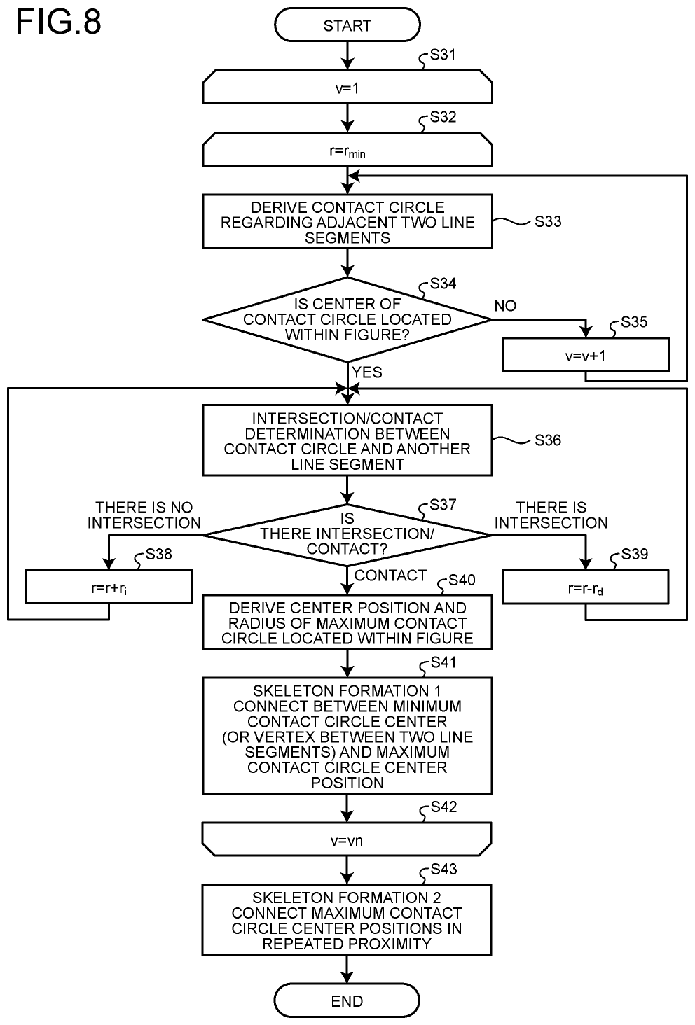

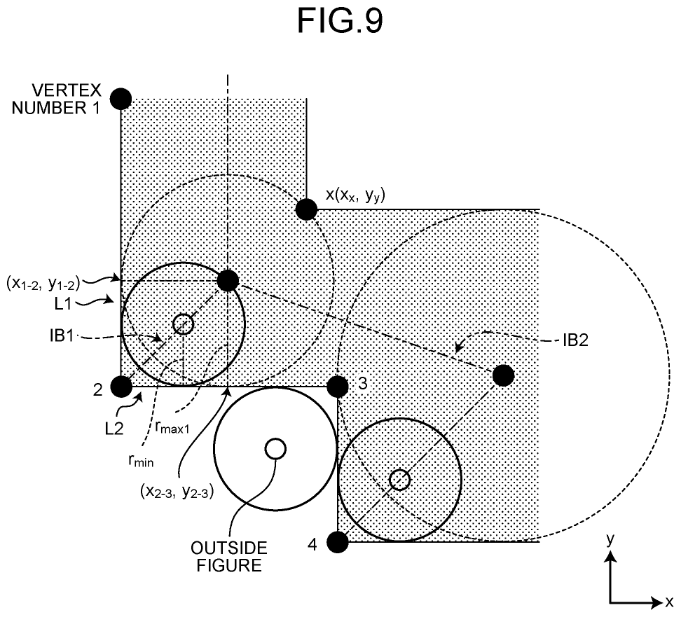

The pattern skeleton extraction processing (S23) illustrated in FIG. 7 may be performed as illustrated in FIGS. 8 and 9. FIG. 8 is a flowchart illustrating pattern skeleton extraction processing in a first modification of the embodiment. FIG. 9 is a diagram illustrating pattern skeleton extraction processing in the first modification of the embodiment. FIG. 9 defines the horizontal direction in the drawing as an x direction, and defines the vertical direction in the drawing as a y direction. The reference direction may be the x direction.

FIG. 8 illustrates a flow of skeleton extraction (skeleton formation) from one figure within the pattern in the mask data. It is assumed that vertices (1 to vn) constituting the pattern figure are arranged counterclockwise.

First, an initial value 1 is set as a parameter v of the vertex number (S31), and an initial value rₘᵢₙ is set as a parameter r of the radius of a circle inscribed within the pattern (hereinafter, referred to as a contact circle) (S32). In an attempt to derive a contact circle regarding two line segments entering and exiting the vertex 1 (S33), the two line segments entering and exiting the vertex 1 are on the same straight line, disabling formation of a contact circle. Therefore, it is determined that the center of the contact circle is not located within the figure (No in S34), and the parameter v is incremented (S35).

Accordingly, the start point is substantially set at a vertex 2 as a vertex of interest. a contact circle, regarding two line segments L1 and L2 respectively entering and exiting the vertex 2, and having a radius rₘᵢₙ, is generated (S33). In FIG. 9, an initial contact circle is indicated by a solid line. At this time, the value rₘᵢₙ is an initial value for an initial determination of whether the center of the contact circle of the two line segments entering and exiting the vertex of interest is located inside the figure or outside the figure, and thus, is a value not particularly limited. Still, the value is preferably to be set to a value that depends on a mask resolution field Wₘᵢₙ or a value of a minimum segment constituting the figure. Here, rₘᵢₙ=Wₘᵢₙ/√(2).

When it is assumed that the center of the contact circle is located within the figure (Yes in S34), the intersection/contact determination between the contact circle and another line segment is performed (S36). When there is no intersection/contact (“There is no intersection” in S37), the radius of the contact circle of the vertex 2 of interest is increased (S38). When there is no intersection or contact, the loop of S37->S38->S36->S37 is repeated.

When there is no contact but there is an intersection (“There is intersection” in S37), the radius of the contact circle of the vertex 2 of interest is decreased (S39). When there is no contact but there is an intersection, the loop of S37->S39->S36->S37 is repeated.

The amount of change in the radius of the contact circle in S38 and S39 does not have to be constant, and it is preferable to vary for each processing. For example, when it is determined that there is an intersection in the intersection/contact determination of a certain contact circle whose radius has been increased by ri, the processing proceeds to S39, in which the radius decrement amount rd is set to rd<ri. The amount of change in the radius is determined in accordance with the degree of intersection regarding the contact circle.

With this operation, when the contact circle comes into contact with an edge or vertex other than the two line segments L1 and L2 entering or exiting the vertex 2 (“contact” in S37), the inscribed circle at that time is set as a maximum contact circle, the coordinates of the center position of the set circle are obtained, and the radius rₘₐₓ is obtained. In the case of FIG. 9, the maximum contact circle is indicated by a dotted line. The maximum contact circle comes in contact with the line segments L1 and L2 and the vertex x (xₓ, y_{y}). The coordinates of the contact points of the maximum contact circle and the line segments L1 and L2 are (x₁₋₃, y_{1-c}) and (x₂₋₃, y₂₋₃) respectively, with the coordinates of the center of the maximum contact circle being (x₂₋₃, y₁₋₂).

The vertex 2 of interest and the centers of two circles, individually having radius Imin and a radius rₘₐₓ, are located on a straight line, so as to perform skeleton formation 1 in which a line connecting the vertex 2 of interest and the maximum contact circle is defined as a pattern skeleton IB 1 (S41). In FIG. 9, the pattern skeleton IB 1 is indicated by a one-dot chain line. Similarly, the figure is explored while moving with the vertex of interest counterclockwise, so as to obtain a maximum contact circle for each vertex of interest.

When the vertex of interest reaches the last vertex vn (S42), an operation to be performed is skeleton formation 2 in which a line connecting the centers of the maximum contact circles is defined as a pattern skeleton IB 2 (S43). In the skeleton formation 2, the centers of the maximum contact circles in repeated proximity are connected to each other, enabling the formation of the skeleton IB 2. In FIG. 9, the pattern skeleton IB 2 is indicated by a two-dot chain line. Although vertices up to the vertex 4 is illustrated in FIG. 9 for simplification, actually, a line connecting the centers of individual maximum contact circles up to the vertex immediately before the vertex 1 in one round movement on the figure is set as the pattern skeleton IB 2.

Note that, in the flow of FIG. 8, in a case where the center of the contact circle is outside the figure, the vertex number is incremented (S35) and reaches the last vertex vn (S42) to complete the operation, with substantially no processing performed. The flow of FIG. 8 exemplifies skeleton extraction of a portion inside the pattern (data portion). In practice, however, MRC inspection of portions outside the pattern (non-data portion) is also performed. When the center of the contact circle is located outside the figure, the maximum contact circle in contact with the vertex or the line segment of another figure is obtained, and the skeleton formation outside the figure (between figures) can be performed by the procedure described above.

Alternatively, by using data in which a data portion and a non-data portion are inverted, it is possible to perform skeleton formation outside the figure (between figures) by the flow of FIG. 8.

As mentioned in the embodiment, by adding the formed pattern skeleton information to the ILT mask data, the data can be utilized for MRC inspection in the mask manufacturing apparatus 200.

In a case where the complexity of the pattern in the ILT mask data is higher, processing may be performed with raster data such as a bitmap data. With processing performed with raster data, even when a pattern has a complicated shape, the pattern formed with pattern data recorded as a pixel group formed in a lattice shape can be regarded as a figure group that has subjected to segmentation processing with the pixel size.

In addition, when the data format to be handled is changed to a new format, the line segment connecting the vertices might have an arbitrary angle or curve in the new data format. Still, by performing skeleton formation in accordance with the format of the data, an appropriate pattern data inspection can be performed.

In this manner, in the inspection processing S3 and S7, by using the locus of the center of the circle inscribed within the pattern and between the patterns, the skeleton within the pattern and the skeleton between the patterns can be extracted.

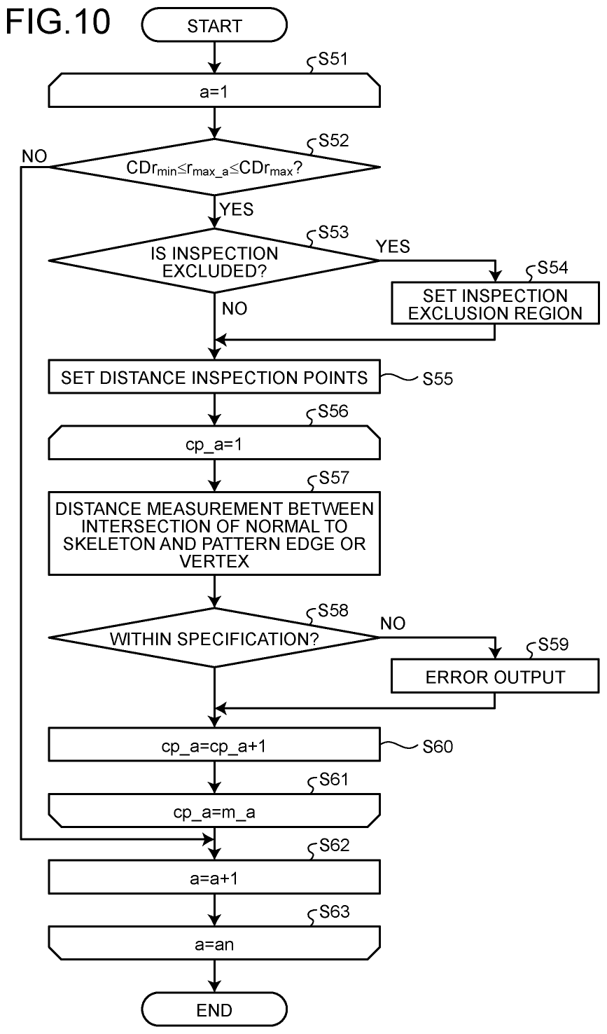

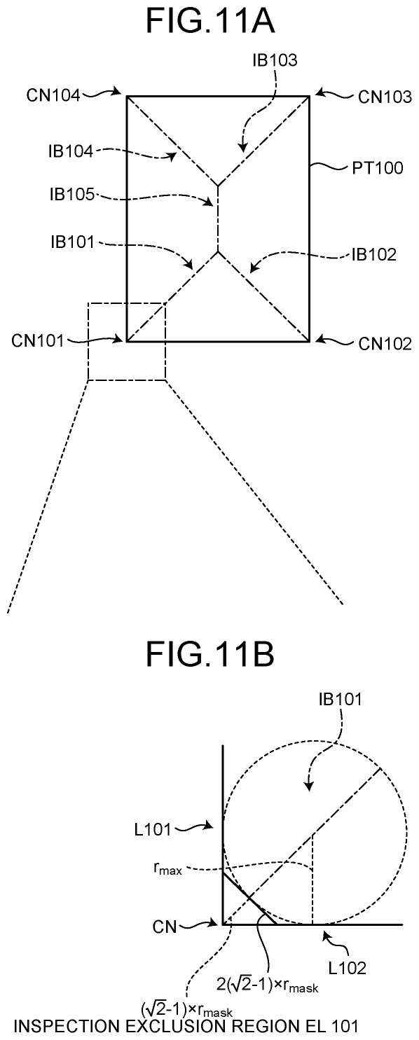

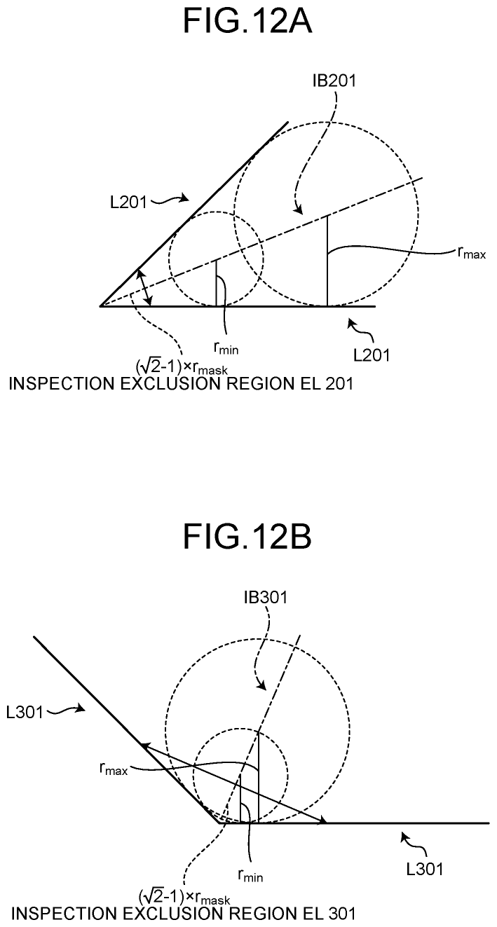

In addition, as a second modification of the embodiment, a part of the skeleton extracted in the pattern skeleton extraction processing may be excluded from the inspection target. For example, in the pattern data inspection processing (S26) illustrated in FIG. 7, pattern data inspection processing including inspection target exclusion setting may be performed as illustrated in FIGS. 10 to 12B. FIG. 10 is a flowchart illustrating pattern data inspection processing according to the second modification of the embodiment. FIGS. 11A and 11B are diagrams illustrating an inspection target exclusion setting in the second modification of the embodiment. FIGS. 12A and 12B are diagrams illustrating an inspection target exclusion setting in the second modification of the embodiment.

Similarly to the first modification of the embodiment, any data format can be applied to the data to be used. For example, in a case where the data to be used is vector data describing vertex coordinate information constituting each figure generated by segmentation processing performed on an ILT ideal mask figure output by the ILT processing, the angle formed by two line segments connecting the vertices is assumed to be 0 degrees or 90 degrees in each piece of data. Alternatively, when other data formats are applied to the data to be used, two line segments each connecting the vertices can intersect each other to form an acute angle or an obtuse angle in each piece of data. Hereinafter, a case where two line segments connecting the vertices can intersect each other so as to form an acute angle or an obtuse angle in each piece of data will be exemplified.

FIG. 10 illustrates a flow of pattern data inspection processing regarding a distance inspection of one figure having pattern data.

In accordance with the size to be detected in the pattern data inspection processing, an upper limit CDrₘₐₓ and a lower limit CDrₘᵢₙ of a radius Imax a of a maximum contact circle at generation of the skeleton to be an inspection target are set in advance. Inspection is performed while sequentially focusing on the skeletons.

It is assumed that the number of skeletons included in one figure is an. An initial value 1 is set to the parameter a of the skeleton number (S51). It is determined, regarding the skeleton of interest, whether the radius of the maximum contact circle at skeleton formation falls within a preset range (S52). When the size is out of the range (No in S52), the value of the parameter a is incremented, and the processing proceeds to the next skeleton.

When the size is within the range (Yes in S52), it is determined whether to set an inspection exclusion region on the skeleton of interest (S53). The mask pattern drawn by the mask drawing apparatus 220 might have rounded corners caused by the mask process, leading to the mask pattern edge placement deviating from the mask data in some cases.

For example, in a rectangular pattern PT illustrated in FIG. 11A, a plurality of skeletons IB 101 to IB 105 within the pattern are extracted. However, pattern edges in the vicinity of corners CN 101 to CN 104 of the rectangular pattern PT are rounded, and can be greatly different from the edges on the data. In the distance inspection in the pattern data inspection (S26), a portion that is not resolved due to the rounding of the corner CN is to be excluded from the inspection target because it is difficult to accurately perform the inspection on the portion.

That is, when the skeleton of interest is the skeleton in the vicinity of the corner CN, it is determined as including a portion to be excluded from the inspection (Yes in S53), and inspection target outside region setting (S54) is performed. For example, here is an assumable case where the skeleton IB 101 of FIG. 11A is the skeleton of interest. In this case, the skeleton IB 101 is defined as a skeleton in the vicinity of the corner CN 101, leading to a concept of a circle, as illustrated as a dotted circle in FIG. 11B, that is in contact with two line segments L 101 and L 102, being segments entering and exiting the corner CN 101, and that has a radius equal to corner rounding (rₘₐₛₖ) due to the mask process. Since this circle has a predicted rounded shape of the corner CN 101, it is referred to as a corner shaping circle. Based on this, a portion deviated from the corner shaping circle toward the corner CN 101 is set as an inspection target outside region EL 101 regarding the skeleton IB 101. When the radius of the corner shaping circle is rₘₐₛₖ, the inspection target outside region EL 101 is a portion having a length (√(2)-1)×rₘₐₛₖ from the end on the corner CN 101 side of the skeleton IB 101. In FIG. 11B, the inspection target outside region EL 101, among the skeleton IB 101, is indicated by a dotted line segment, and the remaining portion of the skeleton IB 101, which is not excluded, is indicated by a one-dot chain line segment.

FIG. 11B illustrates a case where the corner CN 101 is substantially right angle. However, in a case where a corner CN 201 has an acute angle as illustrated in FIG. 12A, there is also formation of a corner shaping circle which has a predicted rounded shape of the corner CN 201 and which is in contact with two line segments L 201 and L 202 on the circumference of the maximum inscribed circle. Based on this, a portion deviated from the corner shaping circle toward the corner CN 201 is set as an inspection target outside region EL 201 regarding a skeleton IB 201. When the radius of the corner shaping circle is rₘₐₛₖ, the inspection target outside region EL 201 is a portion having a length (√(2)-1)×rₘₐₛₖ from the end on the corner CN 201 side of the skeleton IB 201. In FIG. 12A, the inspection target outside region EL 201, among the skeleton IB 201, is indicated by a dotted line segment, and the remaining portion of the skeleton IB 201, which is not excluded, is indicated by a one-dot chain line segment.

In a case where a corner CN 301 has an obtuse angle as illustrated in FIG. 12B, there is also formation of a corner shaping circle which has a predicted rounded shape of the corner CN 301 and which is in contact with two line segments L 301 and L 302 on the circumference of the maximum inscribed circle. Based on this, a portion deviated from the maximum inscribed circle toward the corner CN 301 is set as an inspection target outside region EL 301 regarding a skeleton IB 301. When the radius of the corner shaping circle is rₘₐₛₖ, the inspection target outside region EL 301 is a portion having a length (√(2)-1)×rₘₐₛₖ from the end on the corner CN 301 side of the skeleton IB 301. In FIG. 12B, the inspection target outside region EL 301, among the skeleton IB 301, is indicated by a dotted line segment, and the remaining portion of the skeleton IB 301, which is not excluded, is indicated by a one-dot chain line segment.

When the skeleton of interest is not the skeleton in the vicinity of the corner CN, it is determined as not including a portion to be excluded from the inspection (No in S53), and S54 is skipped.

Next, a distance inspection point is set in a range where the distance inspection is to be performed (S55). The range in which the distance inspection is to be performed is a region remaining after the inspection exclusion region has been excluded in the skeleton of interest. Setting of m_a distance inspection points is performed within the range in which the distance inspection is to be performed. The distance measurement is performed while sequentially focusing on the distance inspection points.

An initial value 1 is set to a parameter cp_a of the distance inspection point number (S56). Here, there is an assumed normal to the skeleton of interest at the distance inspection point corresponding to the parameter cp_a. A distance between intersections of the normal and pattern edges or vertices is measured (S57).

When the measured distance is out of specification (No in S58), an error is output (S59). Information of the error may be added to the mask data so as to be associated with the distance inspection point.

In a case where the measured distance is outside the specification, a length (run length) outside the specification along the skeleton may also be measured in a case where data inspection is performed according to a length of continuation of the dimension outside the specification.

When the measured distance is within the specification (Yes in S58), S59 is skipped.

The value of the parameter cp_a is incremented (S60), and the processing proceeds to the next inspection point.

When the parameter cp_a reaches the maximum value m_a (S61), the parameter a of the skeleton number of interest is incremented (S62), and similar processing is performed on the other skeletons.

Note that these steps can be similarly performed on other patterns and between patterns.

In this manner, in the pattern data inspection processing, the pattern inspection can be performed excluding a region known to be an error in advance. This can reduce the frequency of error output and, achieving high efficiency in the pattern data inspection processing.

In addition, as a third modification of the embodiment, the skeleton extracted by the pattern skeleton extraction processing may be used in the MPC correction of the mask data. The degree of deviation of the edge position of a pattern drawn on the mask from the edge position of the pattern can be predicted to some extent by empirical rules. The deviation of the pattern edge position from the edge position on data is considered to have a certain degree of symmetry with respect to the skeleton in consideration of optical symmetry in the drawing of the electron beam. Therefore, the accuracy of the MPC correction is expected to be improved by applying empirical rules to the skeleton to perform the MPC correction.

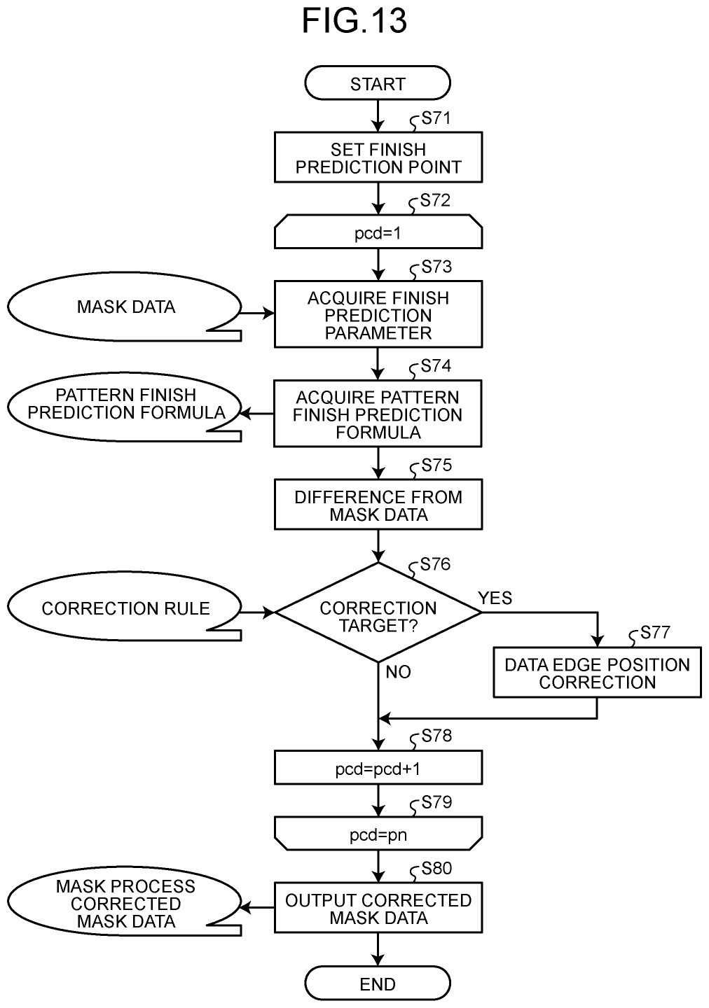

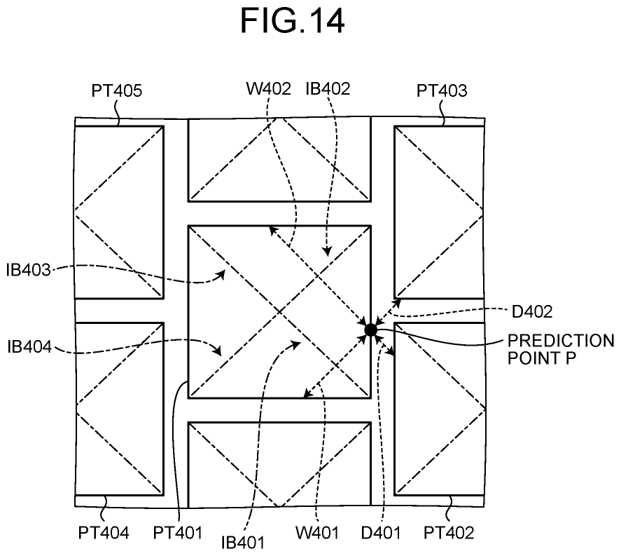

The correction processing S5 illustrated in FIG. 1 may include processing as illustrated in FIGS. 13 and 14. FIG. 13 is a flowchart illustrating correction processing in the third modification of the embodiment. FIG. 14 is a diagram illustrating correction processing in the third modification of the embodiment.

First, a prediction point for predicting the pattern dimension is set on the edge of the pattern as a correction target in the ILT mask data or the mask data (S71). On the edge of the correction target pattern, pn prediction points are set. The correction is performed while sequentially focusing on the prediction points.

An initial value 1 is set to a parameter pcd of the prediction point (S72), and the pattern edge placement prediction parameter is acquired (S73).

Data correction mainly includes two modes: a rule based mode and a model based mode. In the rule based mode, when the acquired dimension is a correction target, the edge position of the pattern data is corrected following a preregistered correction table. In the rule based mode, the pattern edge placement is predicted based on the acquired dimension and a mask pattern edge placement prediction model. When there is a large difference between the predicted pattern dimension and the mask data and the pattern data is to be corrected, the edge position of the pattern data is corrected.

Regardless of the correction mode, it is necessary to clarify the dimensional definition of the pattern in order to perform the pattern data correction.

The following will exemplify processing of constructing a model that predicts the the mask pattern edge placement from the dimensional definition and the mask process characteristics described in the embodiment or the first modification thereof and performing data correction.

For the mask process characteristic regarding Line/Space, the edge placement error corresponding to one skeleton can be expressed by the following Formula 1.

$$edge placement error : Δedge = F ( f ( W ) , gD ) = a \times f ( W ) + b \times gD \qquad Formula 1$$

In Formula 1, W is a parameter indicating a pattern width. D is a parameter indicating an inter-pattern distance. Formula 1 indicates that the pattern edge position with respect to the edge position on the pattern data varies as a edge placement error depending on the pattern width and the inter-pattern distance on the mask data. a is a coefficient indicating the degree of impact of the pattern width on the edge placement error. b is a coefficient indicating the degree of impact of the inter-pattern distance on the edge placement error. Therefore, the parameter W indicating the pattern width and the parameter D indicating the inter-pattern distance can be acquired as the pattern edge placement prediction parameters.

For example, FIG. 14 illustrates a layout configuration in which hole patterns PT 401 to PT 405 indicated by solid lines are arranged in a staggered array. Each of the hole patterns PT 401 to PT 405 has a complicated shape (refer to FIG. 4) in practice, but is illustrated as a rectangular shape for simplification. On the hole pattern PT 401, skeletons BT 401 to BT 405 indicated by one-dot chain lines are extracted. A prediction point of interest corresponding to the parameter pcd=1 is indicated as P.

It is considered that the edge position of the prediction point of interest P is determined from a pattern width W 401 corresponding to a skeleton IB 401 within the pattern, a pattern width W 402 corresponding to a skeleton IB 402 within the pattern, an inter-pattern distance D 401 corresponding to a skeleton IB 401 within the pattern, and an inter-pattern distance D 402 corresponding to a skeleton IB 402 within the pattern. FIG. 14 illustrates processing of acquiring the inter-pattern distance based on the skeleton IB within the pattern, but the inter-pattern distance may be acquired based on skeletons OB between patterns.

Next, a pattern edge placement error prediction formula is acquired (S74). The pattern edge placement error prediction formula is based on a mask process model. The mask process model is determined by matching the actual mask pattern edge placement with parameters for performing mask prediction. Here, it is considered that a variation Δedge_total of each edge position is given by the following Formula. That is, Formula 2 can be acquired as the pattern edge placement prediction formula.

$$Δedge\_total = \sum F ( f ( {W}_{i} ) , g ( {D}_{i} ) ) \qquad Formula 2$$

The difference between the edge position on the data and the edge position at the prediction point of interest is obtained using the obtained pattern edge placement prediction formula (S75). For example, Formula 2 indicates that, by totaling the edge placement error obtained by a pattern width Wi corresponding to an i-th skeleton and an inter-pattern distance Di corresponding to the i-th skeleton for a plurality of skeletons having an impact on the position, it is possible to obtain the variation Δedge_total of the edge position. In the case of FIG. 14, the variation Δedge_total of the edge position can be obtained by totaling Formula 2 for i=401, 402.

Based on the difference obtained in S75, it is determined whether the prediction point of interest is a correction target (S76).

When the variation Δedge_total of the edge position exceeds a threshold, it is determined that the prediction point of interest is the correction target (Yes in S76), and the edge position on the data is corrected (S77). The correction can be performed so as to cancel the variation Δedge_total of the edge position.

When the variation Δedge_total of the edge position is the threshold or less, it is determined that the prediction point of interest is not the correction target (No in S76), and S77 is skipped.

The parameter pcd of the prediction point number of interest is incremented (S78), and the processing proceeds to the next prediction point of interest. When the processing is performed on the last prediction point of interest (S79), the corrected mask data is output to the mask drawing part 206.

According to the processing illustrated in FIG. 13, even with a complicated pattern, it is possible to perform dimensional definition and MPC correction. Construction of a mask pattern edge placement prediction model or creation of a correction table uses information such as a pattern coverage ratio in addition to a dimension value. Other parameters may also be included in the complex pattern.

In this manner, the correction processing corrects the pattern in the mask data using the skeleton extracted in the pattern skeleton extraction processing. This makes it possible to perform high-accuracy pattern edge placement prediction in the correction processing, leading to achievement of high-accuracy correction processing.

Note that the pattern skeleton extraction processing (S23) may be performed before S71 illustrated in FIG. 13, for example, in the correction processing S5. In this case, the pattern skeleton extraction processing (S23) in the inspection processing S3 and S7 may be omitted.

In addition, as a fourth modification of the embodiment, the following will give a utilization example of a pattern skeleton extracted in the second modification of the embodiment.

### (Pattern Skeleton Utilization Example 1)

The pattern skeleton has information regarding the shape and size of pattern data. In the case of a pattern skeleton generated by occurrence of a contact circle, the center position of the contact circle and the medial axis connecting the center positions indicate the shape of the pattern, and the radius of the contact circle, that is, the distance between the center of the contact circle and the contact point of the vertex or line segment of the pattern figure indicates the size of the pattern.

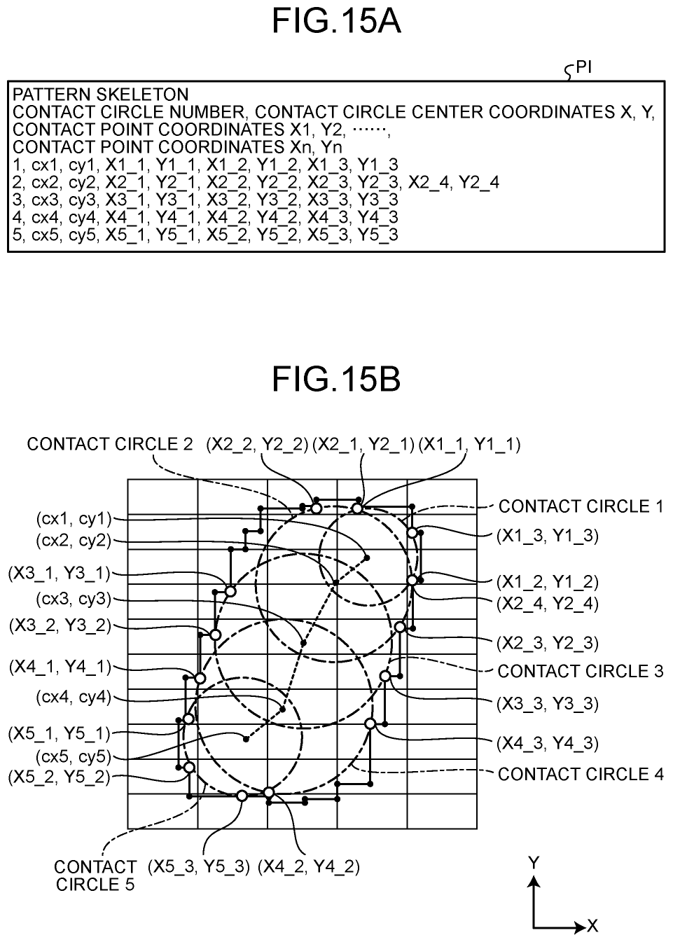

For example, the number of vertices of the pattern figure illustrated in FIG. 15B is 40. FIGS. 15A and 15B are diagrams illustrating a utilization example of an extracted skeleton in the fourth modification of the embodiment. FIG. 15B defines the horizontal direction in the drawing as an X direction, and defines the vertical direction in the drawing as a Y direction. The maximum contact circles when the pattern skeleton is generated by the pattern figure are five circles, namely, a contact circle 1 to a contact circle 5 indicated by one-dot chain lines in FIG. 15B. In each maximum contact circle, there are three or four contact points between the contact circle and a vertex or a line segment of the pattern figure, individually. Skeleton information PI illustrated in FIG. 15A includes an identifier of the contact circle, the center position of the contact circle, and the position of the contact point. The identifier of the contact circle includes a contact circle number. The center position of the contact circle includes contact circle center coordinates. The position of the contact point includes contact point coordinates. The contact point coordinates also include coordinates when different contact circles come in contact with each other at the same coordinates. The skeleton information PI can express a pattern figure with coordinates of 21 points (coordinates of 5 centers and 16 contact points).

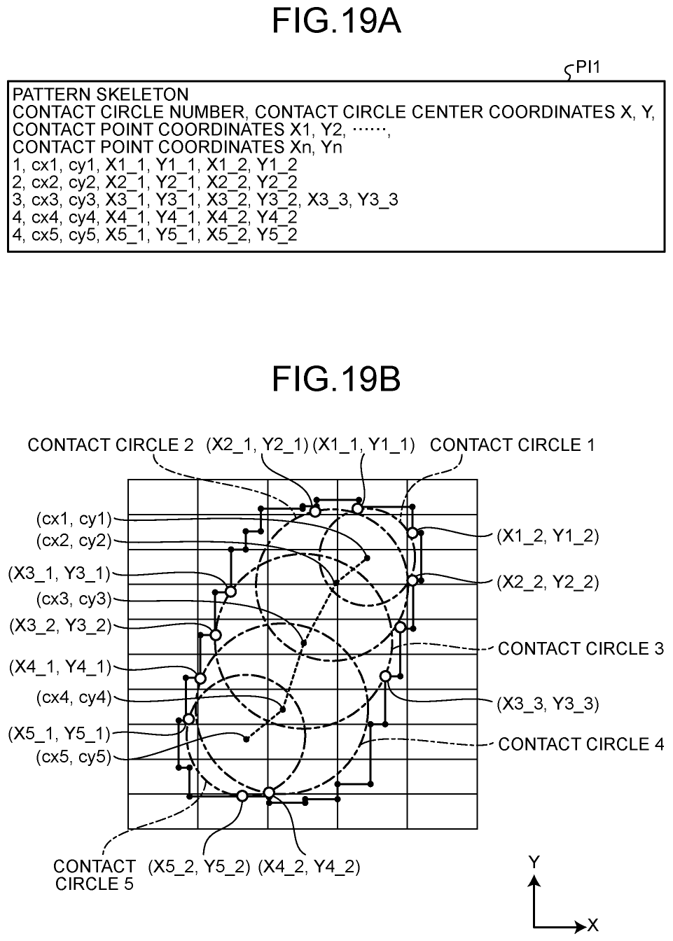

When there are overlapping contact points, one of the overlapping contact points may be omitted. For example, in the case of the pattern figure in FIG. 15B, the contact point (X1_1, Y1_1) of the contact circle 1 and the contact point (X2_1, Y2_1) of the contact circle 2 overlap each other, while the contact point (X1_2, Y1_2) of the contact circle 1 and the contact point (X2_4, Y2_4) of the contact circle 2 overlap each other. Accordingly, the contact point (X2_1, Y2_1) and the contact point (X2_4, Y2_4) of the contact circle 2 can be omitted. Skeleton information PI1 (refer to FIG. 19A), which is obtained by applying such omission on the skeleton information PI, can express a pattern figure by coordinates of 16 points (coordinates of 5 centers and 11 contact points).

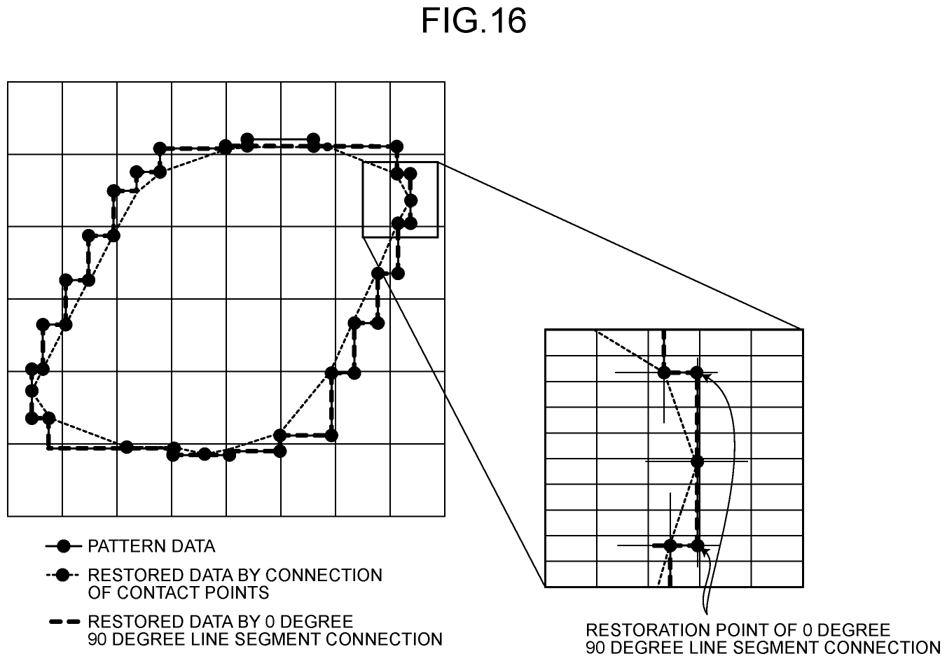

By connecting the contact points of the skeleton information in vicinity with line segments, the original pattern figure can be approximately restored. At this time, the line segments are to be connected so as not to intersect each other. In FIG. 16, the original pattern figure is indicated by a solid line, the figure restored from the skeleton information by a first restoration method is indicated by a dotted line with a narrow pitch, and the figure restored by a second restoration method is indicated by a dotted line with a wide pitch. The first restoration method is a method of restoring an original pattern figure by connecting contact points with one line segment while allowing a line segment inclined with respect to a reference direction (for example, in the horizontal direction in FIG. 16,). The second restoration method is a method of restoring the original pattern figure by connecting the contact points with one or more line segments (while allowing a plurality of line segments) while limiting to line segments of 0 degrees and 90 degrees with respect to the reference direction. As illustrated in FIG. 16, it can be seen that the shape and the size of the figure can be almost restored in both the first restoration method and the second restoration method. Since the original pattern figure is composed of line segments of 0 degrees and 90 degrees, the original pattern figure can be more closely approximated by reconstructing the figure with line segments of 0 degrees and 90 degrees based on each contact point as in the second restoration method. In the second restoration method, an intersection of a cross centered on each contact point and a cross of the adjacent contact point is set as a restoration point of a 0 degree 90 degree line segment connection, and the contact points or the restoration points in the vicinity are connected to each other. With this operation, a dotted line with a wide pitch in FIG. 16 is obtained, making it possible to perform restoration in a shape and size closer to the original pattern figure than in the first restoration method.

In order to faithfully restore the original pattern, it is effective to reduce the minimum contact circle size and form a larger number of medial axes at the time of skeleton formation. However, when the medial axis is formed too precisely, the data capacity compression effect tends to be deteriorated. In addition, when the segment size of the pattern data is smaller than the roundness caused by the mask process, the formed pattern might not be close to the data.

Skeleton formation with appropriate accuracy depending on the resolution of the mask process is effective. The data capacity compression ratio by the conversion of the pattern figure information into the pattern skeleton information varies depending on the complexity of the pattern and the resolution of the mask process (data restoration requirement accuracy). Regarding the trend, the higher the pattern complexity, the lower the pattern information compression ratio.

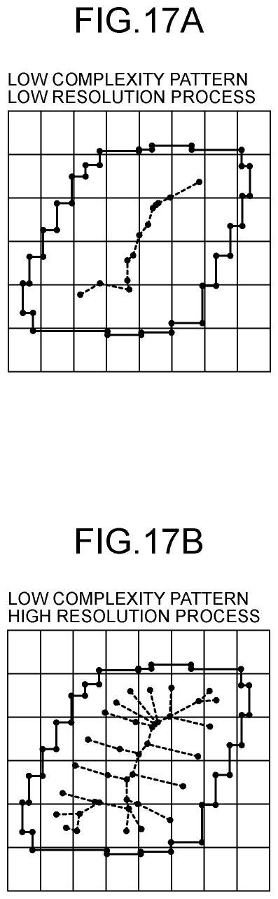

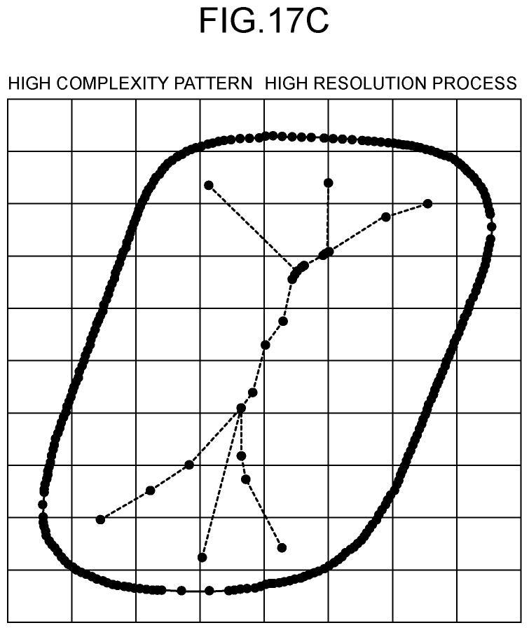

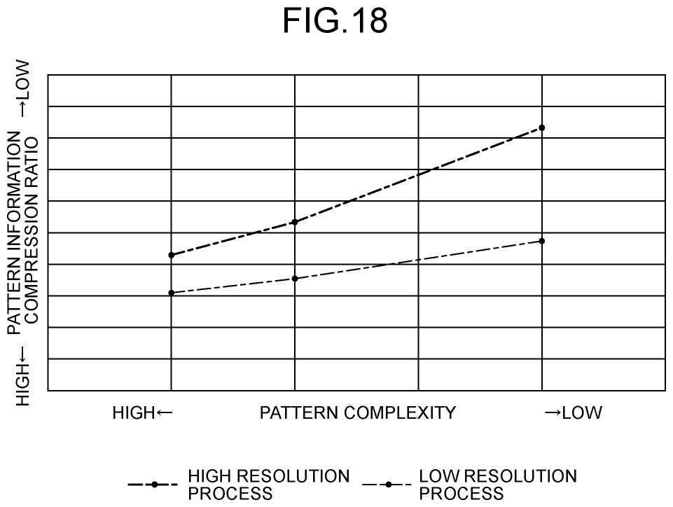

For example, as illustrated in FIGS. 17A and 17B, a pattern with low complexity inherently has low data capacity, and thus, as illustrated in FIG. 18, the data capacity compression ratio when the information is converted into pattern skeleton information is low. FIG. 18 is a diagram illustrating a relationship between pattern complexity and the pattern information compression ratio. In a case where mask process resolution is high, data is restored with higher accuracy as illustrated in FIG. 17B with formation of medial axes with high definition, leading to a lower pattern information compression ratio as illustrated in FIG. 18. FIG. 17A illustrates a pattern figure and a pattern skeleton in the case of a low complexity pattern and a low resolution process. FIG. 17B illustrates a pattern figure and a pattern skeleton in the case of a low complexity pattern and a high resolution process.

In contrast, as illustrated in FIG. 17C, when the pattern complexity is high, the pattern shape is smooth, achieving a high mask process resolution. Therefore, even when the data restoration requirement accuracy is high, there are relatively smaller number of medial axes to form. Consequently, as illustrated in FIG. 18, the higher the complexity of the pattern, the more the effect of data capacity compression by conversion of pattern figure information into pattern skeleton information to be obtained. FIG. 17C illustrates a pattern figure and a pattern skeleton in the case of a high complexity pattern and a high resolution process.

In this manner, converting pattern figure information into pattern skeleton information makes it possible to reduce the data capacity, with a capability of later data restoration, which is effective in terms of data delivery. This effect can be expected to be heightened with higher pattern complexity.

### (Pattern Skeleton Utilization Example 2)

The pattern skeleton generated in the drawing data creation step can be utilized in mask manufacturing.

A mask quality assurance includes dimension measurement of patterns having the same shape and size at a plurality of points in a mask plane, and acceptable/unacceptable (OK/NG) determination performed depending on whether the variation in measurement is within a specification range.

In addition, in a case where a defect of pattern formation failure is detected in the shape inspection step, a pattern shape normally formed by the correction apparatus may be copied so as to perform etching of a portion where no pattern film has been etched or perform embedding of a portion lacking a pattern film.

These cases make it effective to search patterns having the same shape and size from the drawing data.

The following will describe an example of searching for a figure or a group of figures having the same shape and size from the drawing data. A pattern figure to be searched for is referred to as a search target figure.

The search target figure is illustrated in FIGS. 19A and 19B. FIGS. 19A and 19B are diagrams illustrating search target figures according to the fourth modification of the embodiment. Although any pattern figure is applicable as the search target figure, FIG. 19B uses the same pattern figure as that in FIG. 15B. Skeleton information PI1 illustrated in FIG. 19A is substantially the same as skeleton information PI illustrated in FIG. 15A, except for omission of coordinates of contact points overlapping between contact circles. In order to determine whether the pattern figure in the drawing data is the same as the search target figure, the vertex positions of each pattern figure are compared. When the number of vertices constituting the search target figure is a and the number of vertices constituting the pattern figure to be compared in the drawing data is b, the number of vertices to be compared is a×b.

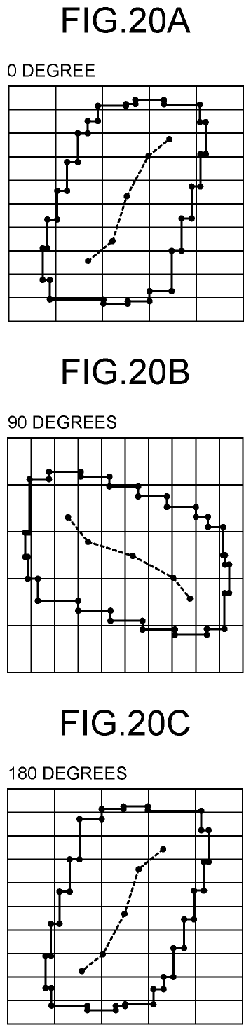

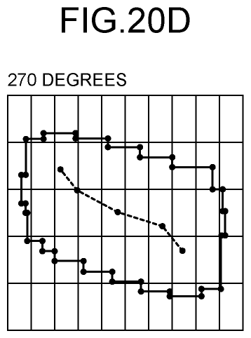

Furthermore, it is assumed that pattern figures in drawing data are arranged in a plurality of directions as illustrated in FIGS. 20A to 20D. FIG. 20A illustrates a case where the pattern figure in the drawing data is arranged at a rotation angle of 0 degrees with respect to the search target figure in FIG. 19B. FIG. 20A illustrates a case where the pattern figure in the drawing data is arranged at a rotation angle of 90 degrees with respect to the search target figure in FIG. 19B. FIG. 20A illustrates a case where the pattern figure in the drawing data is arranged at a rotation angle of 180 degrees with respect to the search target figure in FIG. 19B. FIG. 20A illustrates a case where the pattern figure in the drawing data is arranged at a rotation angle of 270 degrees with respect to the search target figure in FIG. 19B. In this case, a×b×4 times of vertex comparison calculations are required. The number of times is a×b×8 when the pattern figure arranged in the drawing data includes its mirror image.

As mentioned above, the pattern skeletons have information of the shape and size of the pattern data, making it possible to determine whether the figures are the same pattern figure by comparing their pattern skeletons.

The number of vertices of the search target figure illustrated in FIG. 19B is 40, but the number of points of used as the skeleton information PIL is 16. In a case where the same patterns are compared to each other, the number would be 40×40=1600 times when using the number of vertices, while the number would be 19×19=361 times when using the skeleton information PI1, making it possible to greatly reduce the number of times of comparison by using the skeleton information PI1.

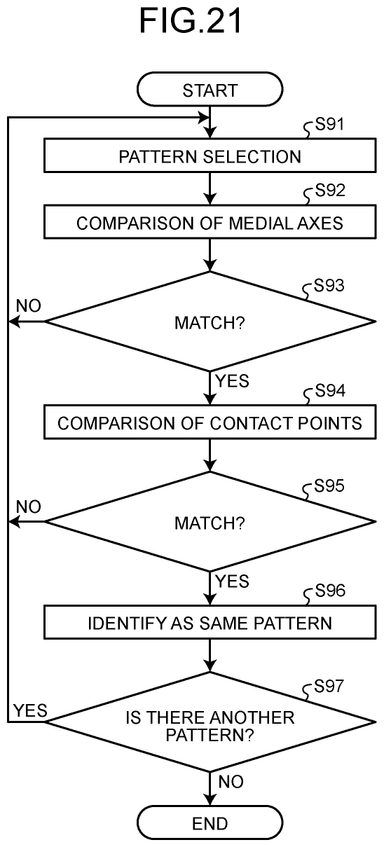

Furthermore, the processing of searching for the same pattern figure may be performed as illustrated in FIG. 21. First, two pattern figures to be compared are selected (S91), the center positions (medial axes) of the contact circles of the two pattern figures are compared with each other (S92). When they do not match (No in S93), the processing returns to S91. When matching is confirmed (Yes in S93), the contact points between the contact circle and the pattern data are compared with each other (S94). When they do not match (No in S93), the processing returns to S91. When matching is confirmed (Yes in S93), the two pattern figures are identified as the same pattern figures (S96). S91 to S96 are repeated until there are no unselected two pattern figures (No in S97). When there are no unselected two pattern figures (Yes in S97), the processing ends. With such processing, it is possible to make a non-matching determination with a small number of comparisons, leading to more efficient operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An inspection method comprising:
extracting a skeleton in a plurality of patterns using data including the plurality of patterns; and
inspecting whether a pattern width of the plurality of patterns or an inter-pattern distance between the plurality of patterns, satisfies a criterion based on the extracted skeleton.

2. The inspection method according to claim 1,
wherein the extraction of the skeleton includes
extracting, by using the data, a first skeleton within the pattern and a second skeleton between the plurality of patterns, and
the inspection includes
inspecting whether each of the pattern width and the inter-pattern distance satisfies the criterion, based on the first skeleton and the second skeleton.

3. The inspection method according to claim 2,
wherein the inspection includes:
obtaining a first parameter related to a distance between two points present within a contour of one pattern, with a line segment connecting the two points intersecting the first skeleton;
determining whether the first parameter satisfies a first criterion;
obtaining a second parameter related to a distance between two points existing separately in contours of two patterns, with a line segment connecting the two points intersecting the second skeleton; and
determining whether the second parameter satisfies a second criterion.

4. The inspection method according to claim 2,
wherein the extraction of the first skeleton includes
obtaining, by using the data, the first skeleton by using a locus of a circle inscribed within the pattern, and
the extraction of the second skeleton includes
obtaining, by using the data, the second skeleton using a locus of a circle inscribed between the plurality of patterns.

5. The inspection method according to claim 1, further comprising
setting a non-resolution portion of the extracted skeleton as an inspection exclusion region after the extraction of the skeleton and before the inspection,
wherein the inspection includes
inspecting whether the pattern width of the plurality of patterns, or the plurality of inter-pattern distances, satisfy a criterion based on a region of the extracted skeleton excluding the inspection exclusion region.

6. The inspection method according to claim 1, further comprising
setting, by using the data, a prediction point on an edge of the pattern,
obtaining a difference between a position in the data and a predicted pattern edge position with using the pattern width and the inter-pattern distance corresponding to the prediction point, and
correcting a position of the prediction point with using the obtained difference.

7. The inspection method according to claim 1, further comprising
restoring the pattern with using information of contact points to the pattern by a circle inscribed within the pattern.

8. A data creation method comprising:
extracting a skeleton in a plurality of patterns using data including the plurality of patterns; and
correcting the plurality of patterns included in the data, based on the extracted skeleton.

9. The data creation method according to claim 8,
wherein the extraction of the skeleton includes
extracting, by using the data, a first skeleton within the pattern and a second skeleton between the plurality of patterns, and
the correction includes
predicting a pattern width and an inter-pattern distance to be drawn on a mask based on the first skeleton and the second skeleton, and correcting at least one pattern among the plurality of patterns in accordance a result of the prediction.

10. The data creation method according to claim 9,
wherein the correction includes:
obtaining a first parameter related to a distance between two points present within a contour of one pattern, with a line segment connecting the two points intersecting the first skeleton;
obtaining a second parameter related to a distance between two points existing separately in contours of two patterns, with a line segment connecting the two points intersecting the second skeleton; and
correcting an edge position of at least one pattern in a case where at least one of a condition that the first parameter deviates from a third criterion and a condition that the second parameter deviates from a fourth criterion, is satisfied on at least one pattern.

11. The data creation method according to claim 9,
wherein the extraction of the first skeleton includes
obtaining, by using the data, the first skeleton by using a locus of a circle inscribed within the pattern, and
the extraction of the second skeleton includes
obtaining, by using the data, the second skeleton using a locus of a circle inscribed between the plurality of patterns.

12. The data creation method according to claim 8, further comprising
setting a non-resolution portion of the extracted skeleton as an inspection exclusion region after the extraction of the skeleton and before the inspection,
wherein the inspection includes
inspecting whether the pattern width of the plurality of patterns, or the plurality of inter-pattern distances, satisfy a criterion based on a region of the extracted skeleton excluding the inspection exclusion region.

13. The data creation method according to claim 8, further comprising
setting, by using the data, a prediction point on an edge of the pattern,
obtaining a difference between a position in the data and a predicted pattern edge position with using the pattern width and the inter-pattern distance corresponding to the prediction point, and
correcting a position of the prediction point with using the obtained difference.

14. The data creation method according to claim 8, further comprising
restoring the pattern with using information of contact points to the pattern by a circle inscribed within the pattern.

15. A non-transitory computer-readable storage medium storing a data creation program, the data creation program causing a computer to execute:
extracting a skeleton in a plurality of patterns using data including the plurality of patterns; and
correcting the plurality of patterns included in the data, based on the extracted skeleton.

16. The non-transitory computer-readable storage medium storing a data creation program according to claim 15,
wherein the extraction of the skeleton includes
extracting, by using the data, a first skeleton within the pattern and a second skeleton between the plurality of patterns, and
the correction includes
predicting a pattern width and an inter-pattern distance to be drawn on a mask based on the first skeleton and the second skeleton, and correcting at least one pattern among the plurality of patterns in accordance a result of the prediction.

17. The non-transitory computer-readable storage medium storing a data creation program according to claim 16,
wherein the correction includes:
obtaining a first parameter related to a distance between two points present within a contour of one pattern, with a line segment connecting the two points intersecting the first skeleton;
obtaining a second parameter related to a distance between two points existing separately in contours of two patterns, with a line segment connecting the two points intersecting the second skeleton; and
correcting an edge position of at least one pattern in a case where at least one of a condition that the first parameter deviates from a third criterion and a condition that the second parameter deviates from a fourth criterion, is satisfied on at least one pattern.

18. The non-transitory computer-readable storage medium storing a data creation program according to claim 16,
wherein the extraction of the first skeleton includes
obtaining, by using the data, the first skeleton by using a locus of a circle inscribed within the pattern, and
the extraction of the second skeleton includes
obtaining, by using the data, the second skeleton using a locus of a circle inscribed between the plurality of patterns.

19. The non-transitory computer-readable storage medium storing a data creation program according to claim 18,
wherein the non-transitory computer-readable storage medium storing the data creation program causing the computer to further execute setting a non-resolution portion of the extracted skeleton as an inspection exclusion region after the extraction of the skeleton and before the inspection, and
the inspection includes
inspecting whether the pattern width of the plurality of patterns, or the plurality of inter-pattern distances, satisfy a criterion based on a region of the extracted skeleton excluding the inspection exclusion region.

20. The non-transitory computer-readable storage medium storing a data creation program according to claim 15,
wherein the non-transitory computer-readable storage medium storing the data creation program causing the computer to further execute setting, by using the data, a prediction point on an edge of the pattern,
obtaining a difference between a position in the data and a predicted pattern edge position with using the pattern width and the inter-pattern distance corresponding to the prediction point, and
correcting a position of the prediction point with using the obtained difference.
